(19) United States
(12) Patent Application Publication
(10) Pub. No.: US 2025/0167157 A1
(43) Pub. Date: May 22, 2025

(54) MICROELECTRONIC DEVICE OBTAINED BY 3D INTEGRATION AND CORRESPONDING PRODUCTION METHOD

(71) Applicant: COMMISSARIAT A L'ENERGIE ATOMIQUE ET AUX ENERGIES ALTERNATIVES, Paris (FR)

(72) Inventor: Pablo RENAUD, Grenoble cedex 09 (FR)

(73) Assignee: COMMISSARIAT A L'ENERGIE ATOMIQUE ET AUX ENERGIES ALTERNATIVES, Paris (FR)

(21) Appl. No.: 18/948,649

(22) Filed: Nov. 15, 2024

(30) Foreign Application Priority Data
Nov. 17, 2023 (FR) 2312671

(51) Int. Cl. H01L 23/00

(52) U.S. Cl. CPC H01L 24/24; H01L 24/03; H01L 24/05; H01L 24/08; H01L 24/19; H01L 24/73; H01L 24/82; H01L 2224/0331; H01L 2224/0362; H01L 2224/05573; H01L 2224/05624; H01L 2224/05647; H01L 2224/08111; H01L 2224/08121; H01L 2224/08145; H01L 2224/19; H01L 2224/24011; H01L 2224/24145; H01L 2224/245; H01L 2224/82031; H01L 2224/82896; H01L 2924/30101; H01L 2924/35

(57) ABSTRACT

A 3D microstructure is formed by hybrid bonding a top wafer on a bottom wafer, by a hybrid bond with metal bonding pads at the interface between the upper metallization level (HBM) of the respective interconnect structure of each of the wafers. These interconnect structures further include a horizontal interconnect level (MX) which is directly below the upper interconnect level (HBM). These pads are distributed horizontally substantially homogeneously and with a fine bonding pitch. Out of these pads, purely bonding pads are electrically insulated from any horizontal metallization element of the horizontal interconnect level (MX). Conversely, bonding and electrical connection pads are electrically coupled, without vias, to an underlying horizontal metallization element formed in the horizontal interconnect level (MX).

### TECHNICAL FIELD

The invention relates in general to the microelectronics industry or semiconductor industry. It concerns more particularly three-dimensional (3D) integration, by vertical assembly of two two-dimensional (2D) microelectronic devices, each formed on a wafer or a die based on a respective semiconductor material, referred to as wafer-to-wafer (W2W) or die-to-wafer (D2W) or die-to-die (D2D) bonding, for the production of a 3D microelectronic device.

More specifically, the invention relates to a 3D microelectronic structure, or 3D microstructure, obtained by bonding a first top wafer to a bottom wafer with a high interconnect density between said wafers, and to a method for producing such a 3D microstructure for the fabrication of an integrated semiconductor product.

The invention is applicable notably to the fabrication of high integration density microsystems and components, such as microelectromechanical systems (MEMS) or nanoelectromechanical systems (NEMS), actuators, radiofrequency (RF) components, power devices or microelectronic devices such as advanced microprocessors, graphics chips, optoelectronic circuits such as image sensors (or imagers) in CMOS (Complementary Metal-Oxide Semiconductor) technology, or the like.

### PRIOR ART

Microelectronic devices that are included in the composition of integrated semiconductor products in a package (or integrated circuits) are produced by essentially planar technological steps. These steps are performed on wafers based on semiconductor material, such as doped silicon. More particularly, a series of technological steps is performed, starting from a flat substrate forming the support of the device, the microstructure being produced always being accessed via the top side of the wafer, also referred to as the front side. The size of a wafer is generally around 200 mm in diameter in 8″ technology or around 300 mm in diameter in 12″ technology.

To be specific, a wafer on which a microelectronic device is produced comprises a substantially flat substrate, with an active zone in the upper part of said substrate in which the active components of the device are produced, and a multilayer interconnect structure formed on top of said active zone of the substrate to connect the active components previously formed, to one another and to the pins of the integrated circuit. Where applicable, the interconnect structure may also incorporate passive components (inductances, capacitors, resistors, etc.) produced in the form of metal elements in the stacked interconnect layers.

The production of the active components of the device in the active zone of the substrate corresponds to the FEOL (Front-End-of-Line) phase of fabrication of the device. The production of the interconnect structure takes place during the BEOL (Back-End-of-Line) phase of fabrication. The specifics of the FEOL phase will not be discussed herein as the invention is implemented during the BEOL phase.

The interconnect structure comprises a stack of interconnect layers, produced in sequence, with horizontal interconnect layers alternating with vertical interconnect layers. The former comprise horizontal metallizations, in other words metal tracks extending parallel to the plane of the wafer to electrically connect respective elements of the active components produced in the active zone of the substrate, and/or where applicable, metal elements forming the abovementioned passive components. The latter comprise vias extending perpendicularly to the plane of the wafer in order to electrically connect together metal tracks and/or passive components belonging to respective horizontal interconnect layers.

The formation of such an interconnect structure by what is known as the Damascene process comprises successively, for each interconnect level to be produced in a stack:
depositing a layer of dielectric material on the top face of the substrate of the microelectronic device, for the first interconnect layer, or on the top face of an interconnect layer already produced, for any interconnect layer subsequent to said first interconnect layer;
etching, in this dielectric layer, trenches (for the horizontal interconnect layers) or via passage holes (for the vertical interconnect layers);
depositing copper (Cu) on the dielectric layer thus etched, in order to fill the trenches and/or the via passage holes, in order to obtain the desired interconnect metal elements; and
chemical mechanical polishing of the excess copper in order to planarize the top surface of the interconnect layer thus produced, with a view to forming another interconnect level on top of the one just produced.

Wafer bonding refers to technology for vertically assembling a first wafer, referred to as the top wafer, on another wafer or bottom wafer, also called a “handle” wafer in reference to its function as a support for the microstructure thus obtained. To this end, the first wafer is turned over vertically and is then aligned and deposited via its front side on the front side of the handle wafer. If a condition of extreme flatness of the top surfaces of the respective wafers thus placed in contact is fulfilled, the Van der Waals forces, in other words microscopic attraction interactions existing for all materials, will ensure adhesion between the bottom and top wafers. In the technical field in question, this is referred to as “bonding”, designating an assembly based on the use of these adhesion forces. The greater the surface area for contact between the two wafers on a microscopic scale, the greater the adhesion, hence the importance of getting rid of any microscopic surface roughness. The top surfaces of the two wafers corresponding to their respective front sides are therefore ultra-polished, prior to their assembly together, so that they are extremely smooth to prevent any bonding defects.

The bonding of two or more wafers, stacked vertically, with or without an intermediate layer, makes it possible to produce a 3D microstructure whereas only 2D production technologies are implemented separately in the FEOL phase of fabrication, to produce microelectronic devices in each of the two wafers, respectively. There are various process flows for producing such a 3D assembly. These various process flows may be adapted accordingly to the specific requirements of the applications in question, which are multiple and varied. This document will be confined to W2W semiconductor wafer hybrid bonding solutions compatible with wafer-level bonding.

The bond between the stacked wafers may be ensured notably by means of bonding pads provided for this purpose. These pads are implanted at respective mutual positions on the top surface of each of the two wafers to be assembled. In practice, the bonding pads are metal elements, which are produced in the dielectric material of an interconnect layer, by implementing a last step of the Damascene process. Such metal bonding pads are therefore harder than the dielectric material of the layer of insulating material in which they are produced.

More specifically, the bonding pads are produced in the last metallization level of each of the wafers, namely the highest metallization level of the interconnect structure of said wafer, in other words also the furthest away from the substrate. This will be referred to below as the HBM (Hybrid Bonding Metal) level. The top side of the bonding pads is therefore exposed at the surface of the interconnect structure of each respective wafer, which is also the surface of the wafer, at the end of the BEOL phase of fabrication.

This way of producing the bonding pads, made of metal, is advantageous for several reasons related, notably, to the hardness of the metal and the technological steps of fabrication of the metal pads. These reasons include, notably:
the rigidity of the top side of the wafer thus obtained (subject to a sufficient density of metal pads);
the accuracy of the patterns for producing the pads (by implementing the Damascene process, which is an efficient and proven technique);
the quality of the polishing that can be obtained by conventional chemical mechanical polishing (notably thanks to the relative hardness of the metal); and
the accuracy of alignment between the wafers that can be obtained using the metal pads to adjust the two wafers in relative positions, etc.

As the bonding pads are made of metal, and more specifically copper within a layer of dielectric material by implementing the Damascene process, they are thus electrically conductive by nature. The bonding of the wafers is said to be “hybrid” because the bonding interface between the wafers is heterogeneous: it comprises metal portions corresponding to the bonding pads, on the one hand, and portions of dielectric material corresponding to the areas between said pads, on the other hand.

Another advantage of producing bonding pads from metal is the possibility of involving the bonding pads in the routing map for routing the electrical signals for the operation of the 3D microstructure ultimately obtained. This routing may be achieved using at least some of the bonding pads to pass current between the bottom wafer and the top wafer, and vice versa, in the 3D microstructure.

The bonding pads thus include:
bonding pads of a first type, which are dedicated exclusively to bonding between the wafers, and which are formed by dummy metallization elements (or dummies, as they are known to those skilled in the art). These pads are not connected either to elements of the microelectronic device produced in the active zone of the wafer or to other passive elements or vias made in the horizontal or vertical interconnect layers, respectively, corresponding to lower metallization levels of the interconnect structure. In other words, they are fully electrically insulated from other conductive elements forming part of active or passive devices of the wafer, by the dielectric material that surrounds them. Therefore, they do not play any role in the functioning of the final microelectronic device other than their basic role of bonding support. They will thus be said to be non-functional bonding pads; and
bonding pads of a second type which both act as bonding support just like the pads of the first type mentioned above but also have the role of providing an electrical connection between the two wafers assembled vertically by this bonding. They are thus involved in the functioning of the final microelectronic device. To render these bonding pads thus functional, during the BEOL phase of production of the individual wafers (hence before bonding thereof) vias are created in at least the vertical interconnect layer directly below. These vias create the electrical connection between, on one hand, the functional pads in question and, on the other hand, elements located lower down, for example active devices (such as transistors or photodiodes, for example) produced during the FEOL phase in the active zone of the corresponding wafer, and/or passive devices (such as for example conductive tracks, capacitors, inductances, etc.) produced during the BEOL phase, in the underlying horizontal interconnect layer of the interconnect structure of the corresponding wafer. The vias connecting the bonding pads of the second type are therefore created in a dedicated metallization level that will be referred to as the HBV (Hybrid Bonding Vias) level.

To sum up, the bonding pads of the first type (non-functional pads or dummies) of each of the two wafers are produced in the last metallization layer of the interconnect structure (in other words, the nth layer for an interconnect structure having n layers) corresponding to the HBM metallization layer, being insulated from any underlying element of said wafer by the dielectric material of the penultimate metallization layer, which is a vertical interconnect layer corresponding to the HBV metallization level; whereas the bonding pads of the second type (functional pads) are also made in the last metallization layer of the interconnect structure but are coupled to active elements of the active zone of the substrate or to passive elements of the antepenultimate layer of the interconnect structure (which is a horizontal interconnect layer) by vias made in the penultimate layer of said structure (which is a vertical interconnect layer corresponding to the HBV metallization level).

Moreover, the number of bonding pads per unit of surface area (including the non-functional bonding pads, on the one hand, and the bonding and connection pads which are functional, on the other hand), and their respective positions on the top surface of the wafers, are dictated by constraints in terms of fabrication and reliability of the microelectronic devices. These constraints are defined in a Design Rules Manual (DRM). Compliance with such design constraints allows the production of fabricable, functional and reliable integrated circuits with the lowest possible energy budget, as economically competitively as possible.

According to these design rules, there must be a minimum density of bonding pads and a virtually homogeneous distribution of said bonding pads on the top side of the wafers to be bonded. This makes it possible to obtain, by chemical mechanical polishing (CMP), a top surface of the wafers to be assembled vertically which is sufficiently flat to create a 3D microstructure without bonding defects. If these design rules are not complied with, it is difficult to obtain wafers with a properly flat top surface. This is because CMP gives rise to differences in topography between areas with a greater or lesser density of metal, depending on the CMP slurry used (phenomenon of erosion). These eroded areas then appear as hollows on the surface and are therefore not bonded during bonding. These surface defects thus take the form of unbonded areas, in other words bubbles at the interface, referred to as voids. These voids weaken the 3D microstructure and make the dies affected by such bonding defects non-functional (because electrical contact is no longer ensured).

The bonding pitch defines the upper limit of the spacing between bonding pads in the horizontal plane XY of the wafer, in other words the maximum centre-to-centre distance between the closest adjacent bonding pads in said horizontal plane XY. This is one of the DRM parameters to be respected in the design of the integrated circuit. The finer the bonding pitch, the greater the interconnect density, and vice versa. The invention applies in particular to embodiments with hybrid bonding of wafers with a high interconnect density, i.e. with a fine bonding pitch, in other words lower than 10 micrometres (μm), for example of the order of 5 μm.

In the prior art referred to above, the differentiation between functional bonding pads and non-functional bonding pads results from the selective formation, before hybrid bonding, of vias in the vertical interconnect layer corresponding to the metallization level “HBV”, directly below the last layer of the interconnect structure corresponding to the metallization level referred to as “HBM”, and in which said bonding pads are made in compliance with the DRM requirements relating to the high interconnect density. This penultimate layer HBV is a vertical metallization layer produced for this sole purpose in the interconnect structure of each of the wafers to be assembled vertically.

The scientific article by Kim et al., “Multi-Stack Wafer Bonding Demonstration Utilizing Cu to Cu Hybrid Bonding and TSV Enabling Diverse 3D Integration”, IEEE 71st Electronic Components and Technology Conference (ECTC)—2021, discloses integration by vertical stacking of three wafers with, in the following order: a bottom wafer, an intermediate wafer, and a top wafer. Unlike what is described for the bond between the intermediate wafer and the bottom wafer, the bond between the top wafer and the intermediate wafer is produced without vias in the conventional sense of the term. In other words, both in the interconnect structure of the top wafer and in the interconnect structure of the intermediate wafer provided to be interconnected with said top wafer, there are no vias between metal bonding pads produced in these interconnect structures, on the one hand, and elements (active or passive) produced in lower metallization levels of the wafer in question, on the other hand. The bonding pads of the intermediate wafer and the top wafer that are disclosed in this document are all pads for electrical connection between said intermediate wafer and said top wafer, in other words functional bonding pads, which are also used as bonding pads. In fact, it is as if the bonding pads all have the function of electrical connection pads (in other words the basic function of a via, in reality, but at the interface between the two stacked wafers), being placed in electrical contact in pairs as a result of the vertical bonding between the two wafers.

However, this integration is not compatible with the design rules such as those imposed by CMP for hybrid bonding applications, as set out above. Notably, the document Kim et al. 2021 does not address the problem of the size of the bonding pitch in the integration in question. For example, it does not state that there must be a minimum number of bonding pads per unit surface area and/or that the bonding pads must comply with a certain specific topology of implantation (i.e. a spatial distribution) on the top surface of the semiconductor devices corresponding to the top wafer and to the intermediate wafer. Thus, the bonding support function provided by the vias as disclosed in this document does not appear to be linked to specific morphological considerations relating to bonding pad implantation constraints. On the contrary, the document Kim et al. 2021 simply teaches the use of the vias, which are provided primarily for electrical connection between wafers, as hybrid bonding support, which makes them functional bonding pads. There is nothing in this document to suggest the existence of non-functional bonding pads. However, it would appear that the type of integration described is not viable for fine bonding pitches (of the order of 5 μm) or even standard bonding pitches (up to 10 μm). To be specific, for microstructures with a high interconnect density, the bonding pads cannot in practice be limited to functional bonding pads, the number, location and distribution of which are dictated only by the routing map, without taking into account the requirements of the DRM in relation to the interconnect density of the wafers.

Furthermore, this type of integration without a layer of the interconnect structure dedicated to the formation of bonding vias which are not also electrical connection pads (in other words, vertical integration without dummy pads) can only be envisaged if, for hybrid bonding, it is possible to use only pads already provided to ensure an electrical connection function in the 3D microstructure in question. In practice, this solution could possibly be applicable only in simple test structures or daisy chains, for laboratory applications in which the risk of bonding defects is acceptable. However, it cannot be used in the case of integration of a 3D microstructure, for the fabrication of integrated circuits on an industrial scale for commercial applications. This is because in such a case, the design rules manual (DRM) dictates a minimum density and a substantially homogeneous distribution of bonding pads with the aim of ensuring sufficient interconnect density to prevent bonding defects. Such a density and such a distribution are not generally obtained when the bonding pads are made up exclusively of functional bonding pads provided for other reasons, namely reasons related to the routing map of the 3D microelectronic device.

Document US2021035941A1 discloses a semiconductor device comprising a first semiconductor structure and a second semiconductor structure separated by a bonding interface. Each semiconductor structure has an interconnect layer and a bonding layer having bonding contacts for bonding to the other semiconductor structure. This document addresses the issue of quality of bonding, notably as regards the density of bonding contacts for bonding between the two semiconductor structures. Some of the bonding contacts of the first semiconductor structure are said to be “functional” because they contribute towards an electrical connection through the bonding interface between the two structures. Others are dummy bonding contacts. However, this document teaches that, for the first semiconductor structure, there are areas without bonding contacts owing to the fact that these contacts are formed with interconnects that act as an etch stop and there are areas of the interconnect layer which do not have the latter.

Document US2021327789A1 also discloses the fabrication of a structure by hybrid bonding of two dies, with electrical connection connectors coupled together, on the one hand, coexisting with dummy connectors coupled together, on the other hand. However, the quality of hybrid bonding is not mentioned in relation to the technical function of the dummy connectors.

Document U.S. Pat. No. 10,141,391B2 discloses a three-dimensional (3D) semiconductor structure in which a first bonding oxide layer of a first semiconductor structure is bonded to a second bonding oxide layer of a second semiconductor structure. There are bonding interfaces between metal pads which are dummies, in the sense that they are insulated from the interconnect structures of each die. However, this document does not mention the problem of bonding pad density.

### SUMMARY OF THE INVENTION

The invention aims to propose an alternative to the prior art set out above, which makes it possible to dispense with the layer HBV while still complying with the DRM requirements as regards the density and homogeneity of distribution of the bonding pads.

To this end, the invention has as first subject matter a three-dimensional (3D) microelectronic structure for an integrated semiconductor product, said 3D microelectronic structure comprising a first microelectronic device produced on a top wafer, and a second microelectronic device produced on a bottom wafer on which the top wafer is bonded by hybrid bonding after being turned over vertically, wherein the bottom wafer and the top wafer each comprise a substantially flat substrate and an interconnect structure formed on top of said substrate, wherein:
the respective interconnect structure of each of the top and bottom wafers is a vertical stack of at least two interconnect levels directly superimposed and each comprising a hybrid layer essentially composed of a dielectric material, namely, respectively:
   an upper interconnect level (HBM), with metal bonding pads formed in the dielectric material and adapted to interact with corresponding metal bonding pads in the other wafer for hybrid bonding of the top wafer to the bottom wafer; and,
   a horizontal interconnect level (MX) which is directly below the upper interconnect level, with horizontal metallization elements,
the respective metal bonding pads of each of the top and bottom wafers are distributed substantially homogeneously on the top surface of the upper interconnect level of the interconnect structure of said wafer, with a bonding pitch, defined as the maximum spacing between adjacent bonding pads horizontally in the plane of said top surface, which is below a predetermined associated threshold;
the respective metal bonding pads of each of the top and bottom wafers comprise bonding pads of a first type, which are electrically insulated from any horizontal metallization element in the horizontal interconnect level of the interconnect structure of said wafer; and
the respective metal bonding pads of each of the top and bottom wafers further comprise bonding pads of a second type, which are each electrically coupled to at least one underlying horizontal metallization element formed in the horizontal interconnect level of the interconnect structure of said wafer.

As will be appreciated by those skilled in the art, the first microelectronic device formed on the top wafer and the second microelectronic device formed on the bottom wafer are assembled vertically one on top of the other by full wafer hybrid bonding, by means of a hybrid bond at the interface between the top layer of the respective interconnect structure of each of said of top and bottom wafers.

Some preferred but non-limiting aspects of the method are set out below.

The horizontal interconnect level of the interconnect structure of each of the top and bottom wafers may comprise a passivation film made of electrically insulating material that covers the layer of dielectric material of said horizontal metallization level, the bonding pads of the first type of each of the top and bottom wafers being electrically insulated from any horizontal metallization element in the horizontal interconnect level of the interconnect structure of said wafer, at least by the insulating material of the passivation film covering the layer of dielectric material of said horizontal metallization level.

The layer of dielectric material of the upper interconnect level of the interconnect structure of each of the top and bottom wafers may be a hybrid layer of dielectric material with patterns, said patterns defining:
solid zones of said dielectric material;
first vertical through zones filled with metal and at which the insulating material of the passivation layer of the horizontal interconnect level is present, said first through zones forming the bonding pads of the first type of the upper interconnect level; and
second vertical through zones, filled with metal, and at which the passivation layer of the horizontal interconnect level has an opening, said second through zones forming the bonding pads of the second type of the upper interconnect level, each in electrical continuity with one of the horizontal metallization elements of the horizontal interconnect level through said opening in the passivation layer.

In some embodiments, the associated threshold of the bonding pitch is lower than or equal to 10 μm, preferably of the order of 5 μm.

The dielectric material of the hybrid interconnect layers of the interconnect structure of each of the top and bottom wafers is for example silicon dioxide (SiO2).

The material constituting the metal bonding pads of the upper interconnect level and/or the material constituting the horizontal metallizations of the horizontal interconnect level of the interconnect structure of each of the top and bottom wafers may be a metal selected from the group comprising copper (Cu), gold (Au), titanium (Ti), aluminium (Al), niobium (Nb), and platinum (Pt), or an alloy based on at least one of said metals.

In some embodiments, the electrically insulating material of the passivation film of the horizontal interconnect level of the interconnect structure of each of the top and bottom wafers is a silicon nitride (SiN) or a silicon carbonitride (SiCN).

The substrate of the top wafer and/or the substrate of the bottom wafer may each comprise an active zone with active elements in the upper part of said substrate, and wherein:
the bonding pads of the first type of the interconnect structure of each of the top and bottom wafers are electrically insulated from the active elements of the active zone of the substrate of said wafer, whereas,
at least some of the bonding pads of the second type of the interconnect structure of the top wafer and/or of the bottom wafer are electrically coupled to at least one of the active elements of the active zone of the substrate of said wafer.

The invention also relates to a method for producing a three-dimensional (3D) microelectronic structure, according to the first aspect above, comprising the hybrid bonding of a top wafer on a bottom wafer after turning said top wafer over vertically, wherein the prior production of the interconnect structure of each of the top and bottom wafers comprises the formation of a vertical stack of at least two interconnect levels directly superimposed on top of the substrate of said wafer, namely, respectively:
a horizontal interconnect level (MX), with horizontal metallization elements formed in the dielectric material of a corresponding hybrid layer; and, directly on top of said horizontal interconnect level (MX),
an upper interconnect level (HBM) with metal bonding pads formed in the dielectric material of a corresponding hybrid layer, and adapted to interact with corresponding metal bonding pads in the other wafer, for the hybrid bonding of the top wafer on the bottom wafer,
   and wherein:
the respective metal bonding pads of the upper metallization level of the interconnect structure of each of the top and bottom wafers are produced with a substantially homogeneous distribution on the top surface of said upper metallization level, and with a bonding pitch, defined as the maximum spacing between adjacent bonding pads horizontally in the plane of said top surface, which is below a predetermined associated threshold;
among the respective metal bonding pads of each of the top and bottom wafers, bonding pads of a first type are produced each with electrical insulation from any horizontal metallization element in the horizontal interconnect level of the interconnect structure of said wafer;
among the respective bonding pads of each of the top and bottom wafers, furthermore, bonding pads of a second type are produced each in electrical continuity with at least one underlying horizontal metallization element formed in the horizontal interconnect level of the interconnect structure of said wafer.

In embodiments for implementation of the method, the formation of the upper interconnect level of the interconnect structure of each of the top and bottom wafers may comprise:
depositing a passivation film made of electrically insulating material that covers a hybrid layer of dielectric material comprising horizontal metallization elements in the horizontal metallization level of the wafer;
formation of a layer of dielectric material and first etching by photolithography, in order to etch said layer of dielectric material with an etch stop on the passivation film of the horizontal metallization level in order to form patterns in said layer of dielectric material corresponding to the metal bonding pads in the upper metallization level of the wafer; then,
second etching by photolithography, in order to etch the passivation film of the horizontal metallization level so as to open up said film in only some of the patterns previously formed in the layer of dielectric material which correspond to the metal bonding pads of the second type in the upper metallization level of the wafer; then,
simultaneously filling, with metal, all of the patterns previously formed in the layer of dielectric material, namely both the patterns corresponding to the metal bonding pads of the first type and the patterns corresponding to the metal bonding pads of the second type in the upper metallization level of the wafer.

The patterns in the layer of dielectric material corresponding to the metal bonding pads in the upper metallization level of the wafer may, for example, be filled with metal by electrochemical deposition.

Thus, the bonding pads of the first type of each wafer are formed in the upper layer of the interconnect structure and are electrically insulated from any metallization element formed in any corresponding interconnect layer corresponding to a metallization level lower down in the stack of layers forming the interconnect structure, and from any active element in the active zone of the bottom wafer. This insulation is achieved by the insulating material of the passivation layer associated with the horizontal interconnect layer of the interconnect structure which is directly below said upper layer. These bonding pads of the first type are therefore non-functional pads, i.e. dummy metallizations, which are used only for hybrid bonding.

Conversely, the bonding pads of the second type are bonding and electrical connection pads formed in the upper layer of the interconnect structure, in electrical continuity with a metal element of at least one other horizontal interconnect layer of the interconnect structure which is the metallization layer directly below the upper layer. These bonding pads of the second type are therefore functional pads, serving both for hybrid bonding of the top wafer turned over vertically on the bottom wafer, and for electrical connection between the two devices thus vertically assembled.

The production of the semiconductor product in accordance with the first aspect of the invention above, and the implementation of the method in accordance with the second aspect of the invention above, make it unnecessary to produce a vertical interconnect layer with vias directly below the upper layer of each of the two 2D microelectronic devices to be stacked. This can therefore be dispensed with, as there are functional bonding pads and non-functional bonding pads which make it possible, together, to achieve the desired interconnect density. This makes it possible to comply with the design rules (DRM) to obtain good CMP performance and therefore high quality bonding of the two stacked microelectronic devices.

According to another advantage, the electrical resistance of a functional bonding pad produced in accordance with embodiments for implementation of the method proposed is significantly lower than that of the vertical electrical connections produced by vias according to the prior art. The reduction in interconnect resistance reduces the dissipation of energy by the Joule effect in the integrated circuit in operation, and therefore limits the rise in temperature. This reduction also increases the life of small mobile devices (such as smartphones) incorporating the integrated circuit, when they are battery powered.

To be specific, the electrical resistance of an interconnect is inversely proportional to the surface area for contact between the two interconnect elements placed in electrical contact with one another, all else being equal: the greater this surface area, the more current can pass through the interconnect, and therefore the lower the electrical resistance. As those skilled in the art will appreciate:
in the case of conventional 3D integrations in which the interconnects comprise vias of circular section, the current is limited by the small surface area of the vias with respect to the surface areas of the bonding pads. For microstructures having a bonding pitch of, for example, 5 μm, the diameter of the circular section of a via may be 0.5 μm, such that the cumulative surface area of the four vias produced for a given bonding pad is equal to 4×3.14×(0.25)², in other words to 0.785 μm²; whereas,
in the case of an interconnect obtained by implementing the method according to the invention, it is the total surface area of the pads (considering optimal alignment between the respective pads of the two 2D microelectronic devices) that makes up the electrical connection surface area for the passage of electrons. The contact surface area of square section may then be equal to 2.5×2.5 μm, in other words 6.25 μm², which is around eight times the cumulative surface area of four vias according to a conventional solution, and therefore a through current that may be eight times higher. Even in the event of imperfect alignment, for example with 50% misalignment, the gain in contact surface area is a factor of four, which means that the contact resistance of an electrical connection element is divided by four, at least, with respect to the prior art.

Furthermore, as the bonding pads are directly connected to the lines of metal of the horizontal interconnect layer that is directly below the upper layer of the interconnect structure, this avoids the formation of passivation layers of titanium nitride (TiN) conventionally used in the prior art, which have the disadvantage of being more resistive than metal. Also for this reason, the interconnect resistance is improved (is lower), by virtue of the invention.

According to another advantage, the thickness of each of the wafers may be smaller than in microstructures according to the prior art, since there is no need for an interconnect layer with a level HBV to produce vias for connecting functional bonding pads. Each wafer is therefore subject to lower mechanical stress, resulting in better conditions for bonding of the two wafers. Again, the risk of bonding defects is lower.

Overall, and as will be explained in the detailed description of embodiments of the method, the production method proposed saves on nine technological steps of fabrication, compared to the prior art. The ecological and economic impact, and the time saving compared to known methods, are therefore considerable. Notably, as the cycle time is shorter, there is less take up of water and therefore a lower risk of degassing during annealing. Furthermore there are two fewer annealing operations, which represents a reduction in the overall thermal budget.

### BRIEF DESCRIPTION OF THE DRAWINGS

Further aspects, aims, advantages and features of the invention will become clearer on reading the following detailed description of preferred embodiments of the invention. This description is provided by way of non-limiting example. It refers to the appended drawings, in which:

FIG. 1A is a view, in vertical section, of an example of a 2D microelectronic device, adapted for the production of a 3D microstructure by hybrid bonding to another similar device, according to the prior art;

FIG. 1B schematically depicts the principle of assembly by hybrid bonding, of W2W type, of two 2D microelectronic devices like that shown in FIG. 1A, to obtain a 3D microstructure;

FIG. 1C is a view, in vertical section, of the 3D microstructure obtained by vertical assembly of two 2D microstructures as shown in FIG. 1A, by hybrid bonding as shown in FIG. 1B, according to the prior art;

FIG. 1D is a top view of an example of a 3D microelectronic device according to the prior art, similar to that shown in section in FIG. 1C;

FIG. 2 is a view, in vertical section, of an example of a microstructure according to the second subject matter of the invention;

FIG. 3A to FIG. 3I are views, in vertical section, of an example of a 2D microelectronic device at various stages of its production by means of a method according to embodiments for implementing the first aspect of the invention, making it possible to produce the 3D microstructure of FIG. 2 by vertical assembly of two such identical or similar 2D microelectronic devices;

FIG. 4 is a block diagram showing groups of steps of the method according to embodiments for implementing the method according to the first aspect of the invention, and steps of a method according to the prior art; and,

FIG. 5 is a comparison table, showing correspondence between the steps of a method according to the prior art and steps of the method according to embodiments for implementing the first aspect of the invention, respectively.

### DETAILED DESCRIPTION OF EMBODIMENTS

In the figures and in the remainder of the description, the same reference numerals designate identical or similar elements. Furthermore, the various elements are not shown to scale, for the sake of clarity in the figures. Moreover, the various embodiments and variants described are not mutually exclusive and may be combined with one another.

In the text below, the terms “substantially”, “around” and “of the order of” mean to within 10%, and preferably to within 5%. Moreover, the expression “between A and B” and equivalent expressions mean that the limits A and B are included, unless expressly stated otherwise.

The expression “formed on the basis of”, used with reference to a material and an element of interest, means that the material is a compound formed of a plurality of elements including at least said element of interest.

The expression “material mainly comprising” an element of interest means a material in which at least 50% of the volume is made up of, or comprises said element of interest.

The term “wafer” designates a very thin plaque of monocrystalline semiconductor material, on which microelectronic devices can be produced. Wafers are thus used to fabricate microelectronic devices. Wafers are made with a doped semiconductor material, such as silicon (Si), gallium arsenide (GaAs) or indium phosphide (InP). Wafers have dimensions generally between 25.4 mm (1″ technology) and 300 mm (12″ technology), for a thickness of the order of 0.7 mm. Wafers are used in the microelectronics industry as a support for the fabrication of microstructures. Such fabrication uses design techniques such as, for example and without limitation: doping, etching, deposition of other materials and photolithography. The doped semiconductor material from which the wafer is made therefore serves as a substrate for the creation of microstructures forming the active microelectronic devices which are used in the composition of integrated circuits, transistors, power semiconductor products, MEMS or NENS, etc.

In the fabrication of an integrated circuit, the FE (Front End) phase designates all of the technological steps of fabrication of the circuit before packaging thereof. FE includes the FEOL (Front End Of the Line) phase as well as the BEOL (Back End Of the Line) phase. FEOL designates the first phase, in which all the steps of fabrication of the active components (transistors) are carried out, for example in CMOS technology, in the active zone of the wafer up to (but not including) the first metallization level of the interconnect structure, from the top. BEOL designates the second phase of fabrication of the integrated circuit, which starts from the first metallization level of the stack of metallization layers forming the interconnect structure by means of which the active components of the active zone of the wafer are interconnected to one another according to a routing map for wiring the active components on the wafer. In this second phase, moreover, individual microelectronic devices forming the passive components (capacitors, inductances, resistors, etc.) may be produced in the various metallization levels of the interconnect structure. The metals usually used are copper (Cu) and aluminium (Al). BEOL begins when the first layer of metal is deposited on the wafer. By extension, BEOL is sometimes used to refer to the interconnect structure which includes the insulating (dielectric) layers, the metal tracks (horizontal electrical connections), the vias (vertical electrical connections between the tracks), and the bonding sites for the connections between the die and the package of the integrated circuit.

CMP (Chemical Mechanical Polishing), already mentioned in the introduction, designates a process of smoothing the surface of a wafer using the combined action of mechanical and chemical forces, having the effect of removing the material(s) on the surface of the wafer and eliminating any surface topography, resulting in planarization of the surface of the wafer exposed to this process.

The “Damascene process” is a technique for forming metal elements (also called “metallizations”) in copper, which consists of etching trenches and via holes in a layer of dielectric material, then filling the trenches and via holes with copper to form conductive tracks and vias, respectively, and lastly, planarizing the copper by means of chemical mechanical polishing (CMP).

The “annealing” of a material is an operation corresponding to a cycle of heating, consisting of a step of gradual rise in temperature to temperatures ranging from around 250° C. to 450° C., followed by controlled cooling. Annealing makes it possible to modify the physical characteristics of the material subjected to this heat treatment.

“Electrolytic or electrochemical deposition”, or ECD, is a deposition technique used for the rapid filling of trenches or via holes with a metal such as copper, for example. The principle of implementation is as follows: the wafer is configured as a negative electrode (cathode) and is immersed in an electrolyte, i.e. an electrolytic solution containing metal salts. Copper is deposited from an anode, i.e. a positive counter electrode, made of copper. To this end, the metal ions in the anode are reduced by applying a potential difference between this anode and the cathode. In order for the reaction to occur homogeneously on all the portions of the surface of the wafer as desired, they must be conductive. In other words, it is therefore necessary that the resistivity of the seed layer on the portions of the wafer targeted be as low as possible.

The term “photoresist” designates a material, more particularly a polymer resin, which is sensitive to light and is used to form a pattern on the substrate, using an optical mask made up of opaque zones and transparent zones which define the pattern to be reproduced on the wafer through which the photoresist is illuminated and has its properties modified in the transparent zones of the optical filter. Thus, for example, a “positive” photoresist is a light-sensitive polymer which, when exposed to ultraviolet (UV) light, is converted to a soluble material: areas exposed to this illumination can then be dissolved using a solvent, leaving behind a layer with recessed patterns which can be used as a mask for the formation of a structure through the mask thus formed, for example by etching an underlying material which is selective to the material of the mask, by ion implantation, or by deposition of a new material in the areas exposed by the mask.

Lastly, a direct orthogonal three-dimensional reference frame (X,Y,Z) is defined here and for the remainder of the description, wherein the axes X and Y form a plane parallel to the main plane of the “handle” wafer in question, and wherein the axis Z is oriented substantially orthogonally to the main plane of said wafer, this axis Z being oriented in the direction of gravity. In the remainder of the description, the terms “vertical” and “vertically” are understood to be relative to an orientation substantially parallel to the axis Z, and the terms “horizontal” and “horizontally” relative to an orientation substantially parallel to the plane (X,Y). Furthermore, the terms “top” and “bottom” together with their derivatives (such as “above” and “below”, or “on top of” and “under”), as well as the terms “lower” and “upper”, used to qualify an element of the microstructure in question, are to be understood to relate to a position increasing when moving away from the wafer upwards, i.e. in the vertical direction +Z.

The term “back” and the term “front”, on the other hand, are used with reference to the side of a wafer via which the various treatments are, or have been, carried out to produce the microstructure in question. As these treatments are systematically carried out from above when the wafer is placed flat in an enclosure used to carry out the treatment, the “front” side is generally (and by default) the top side of the wafer. However, when a wafer or a die cut from a wafer is turned over vertically, its front side becomes the bottom side and its back side becomes the top side. The term “back” assigned to the semiconductor substrate of an individual wafer or die is also used in reference to this convention, in the sense that it refers to the part of the substrate which is furthest from the side of said wafer or said die on which treatments have been carried out on the substrate, and which is always referred to as the back side even if the wafer or die has been turned over vertically such that this side is now located at the top and facing upwards.

“Layer” means an extent of material the thickness of which along the axis Z is smaller, for example ten times or even twenty times smaller, than its longitudinal dimensions of width and length in the plane XY.

“Pad” means a volume of a crystalline material, for example based on a specific metal such as copper or aluminium, the thickness of which along the axis Z is substantially equal to its longitudinal dimensions of width and length in the plane XY, and the longitudinal dimensions of which are smaller than or equal to the thickness along the axis Z of a layer in which they are made. The shape of the pad, in a horizontal section plane (parallel to the plane XY) may be polygonal (for example a square or a rectangle), or curved (for example a circle or an ellipse).

Particular embodiments will be described with reference to the non-limiting example of application to the production of a 3D microelectronic structure intended for the fabrication of an integrated semiconductor product, for example in CMOS technology. The embodiments of this 3D microstructure and the embodiments for implementation of the method described may be adapted to the specific aspects of each application concerned without departing from the teachings of the invention.

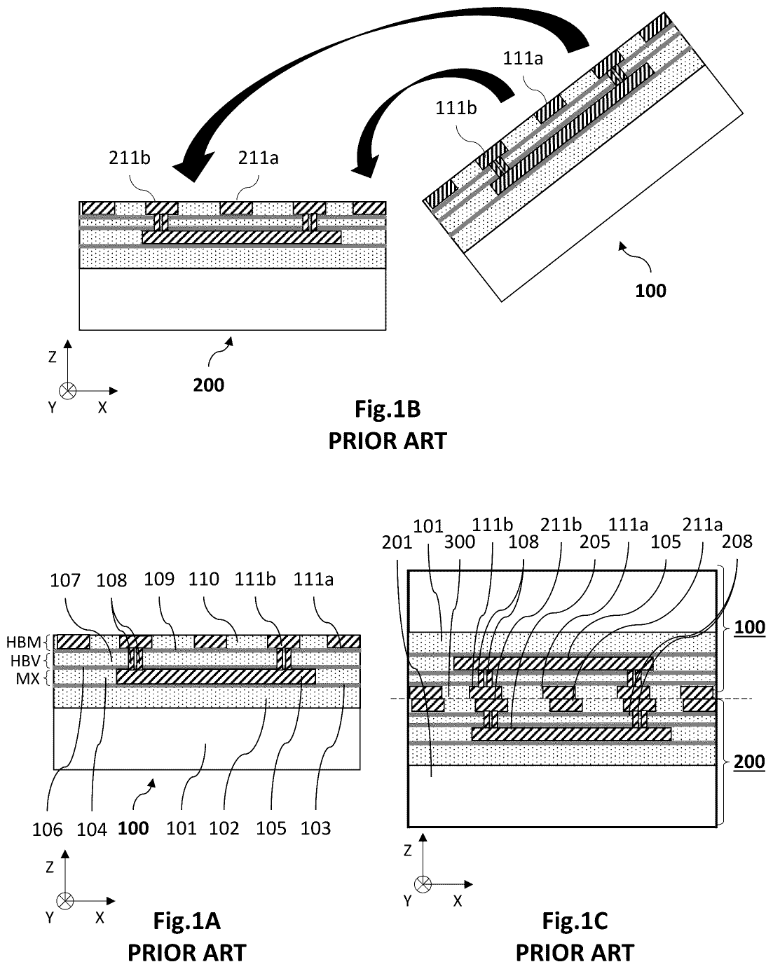

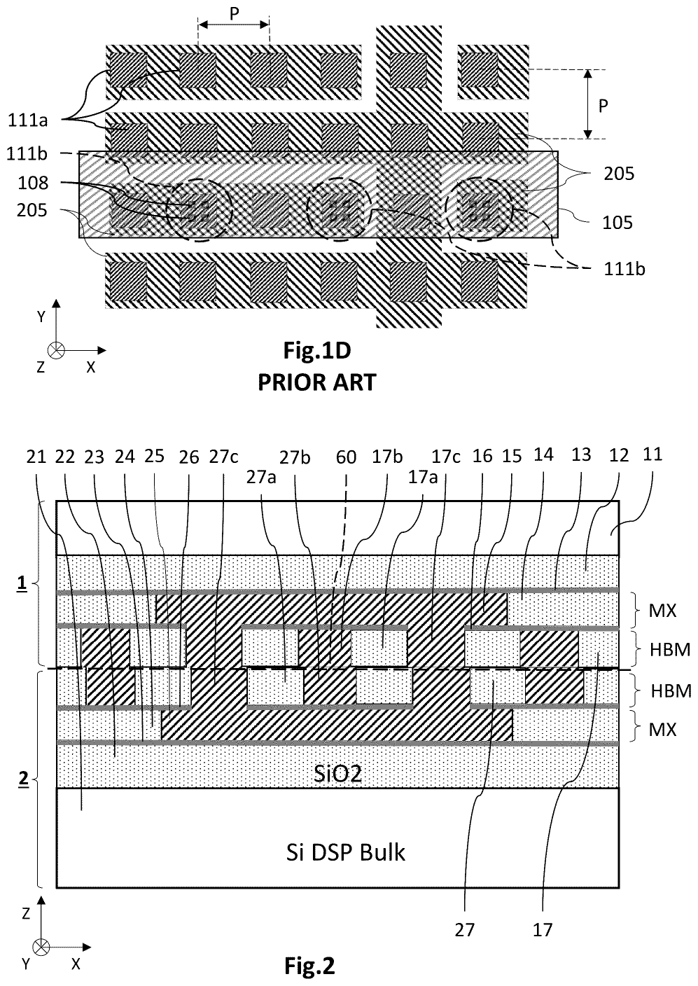

With reference to the schematic drawings in FIG. 1A to FIG. 1D, the principle of 3D assembly by hybrid bonding according to the prior art will first of all be described.

Direct bonding may be used in 3D integration. Two dielectric materials are bonded together to assemble two separate wafers. However, only a mechanical bond is created and there is no electrical continuity at the bonding interface. The electrical connections between the top wafer and the bottom wafer may be established, after bonding, by forming through-silicon vias (TSVs) which are vias with a high aspect ratio that pass right through the SiO2 and/or Si layers from one side of the bonding interface to the other. This technique provides only a low interconnect density between the wafers. Furthermore, it is relatively time-consuming and difficult to implement because the method for implementation of TSVs comprises many etching steps and deposition steps.

Hybrid bonding constitutes another approach which is also well known, per se, to those skilled in the art. According to this approach, two wafers are treated separately, following a conventional integration process up to the production of the last of the standard metallization levels in their respective interconnect structure, namely the n stacked metallization levels also referred to as levels M1, M2, . . . , Mn. After this step, a penultimate metallization level referred to as the Hybrid Bonding Vias (HBV) level and a last (i.e. final) metallization level referred to as the Hybrid Bonding Metal (HBM) level are added vertically to the interconnect structure of each of the wafers, following the Damascene process, after creating the n underlying metallization levels (or levels M1, M2, . . . , Mn). The HBM level constitutes the bonding level of the wafer for hybrid bonding to the other wafer and to this end contains bonding pads. The HBV level, which is directly under the HBM level, only contains vertical metallizations for electrical connection of some of the bonding pads in the HBM level to lower metallization levels M1, M2, . . . , Mn. The difference with respect to the direct bonding mentioned above is the presence of the copper bonding pads in the respective bonding levels of the two wafers, with a high density. The dielectric material in these levels is SiO2 deposited by chemical vapour deposition (PECVD). The very high density of bonding pads present in this SiO2 layer has a number of advantages, not only in terms of electrical connection between the two wafers once assembled by hybrid bonding, but also in terms of the quality of bonding obtained.

With reference to FIG. 1A, a first microelectronic device 100 according to the prior art, for example a CMOS technology device, comprises a substrate 101. The substrate 101 is for example a silicon substrate. On top of the substrate 101, the device 100 comprises a layer 102 of electrically insulating material (dielectric), such as silicon dioxide (SiO2). The layer 102 is itself covered by a passivation layer 103, for example a layer of silicon nitride (SiN).

The microelectronic device 100 comprises an active zone (not shown) at the top of the substrate 101, directly below the insulating layer 102. This active zone may comprise active components, such as transistors, photonic devices such as photodiodes, etc. Such components, where applicable, are produced using for example technological fabrication steps which are conventional steps in CMOS technology microelectronics, in order to produce an integrated circuit for a specific application. This phase of fabrication of the circuit (or FEOL phase) will not be discussed in the present description, because the invention is implemented during the subsequent BEOL phase, namely the phase of production of the interconnect structure. This interconnect structure will now be described, again with reference to FIG. 1A.

To be specific, the microelectronic device 100 comprises an interconnect structure formed of a stack of n layers each corresponding to a respective metallization level, in which n is an integer strictly greater than 1. These n interconnect layers are made essentially of an electrically insulating (dielectric) material, such as silicon dioxide (SiO2). They contain metal elements, namely conductive tracks or vias. These metal elements (also called metallizations for short) are produced by deposition of metal in trenches or via holes respectively, formed beforehand by any ad hoc method, in the dielectric material of the corresponding interconnect layer. The trenches and the via holes are generally formed by photolithographic etching, then filled with metal. The metal in question is generally copper (Cu), but it may possibly be another metal, such as aluminium (Al) for example. The layers of the interconnect structure correspond to respective metallization levels which are generally referred to using the acronyms M1, M2, . . . , Mn in the relevant literature. The horizontal metallization levels comprising conductive tracks produced by deposition of metal in trenches formed in the dielectric material of the corresponding layer alternate with vertical metallization levels comprising vias produced by deposition of metal in via holes formed in the dielectric material of the corresponding layer. The vias of a vertical metallization level are arranged to couple conductive tracks of a metallization level above (where applicable) with conductive tracks of a metallization level below, and/or with active elements of the active zone of the substrate 101.

In the example of FIG. 1A, n is equal to three (n=3): the interconnect structure comprises three layers 104, 107 and 110 stacked vertically, in this order, on top of the insulation layer 102 covering the substrate 101. They are formed successively on top of the substrate 101, one after the other, starting with the lowermost layer and ending with the uppermost layer. In this example, the layer 104 is the bottom layer of the interconnect structure, or lowest layer, in other words also the layer that is closest to the substrate 101. It corresponds to the first metallization level, referenced MX in the figure and in the text below, which is formed directly on top of the substrate 101. On the other side in the vertical direction Z, the layer 110 is the top layer of the interconnect structure, or uppermost layer, in other words also the layer furthest from the substrate 101. It corresponds to the last metallization level which, in the context of the present description, is designated using the acronym HBM (Hybrid Bonding Metal). Lastly, the layer 107 is the penultimate layer in the interconnect structure, formed directly below the top layer 110 with which it interacts directly from a functional point of view, and is designated using the acronym HBV (Hybrid Bonding Vias) in the context of the present description. The function of these three interconnect layers, namely the metallization levels MX, HBM and HBV, is described in detail below.

In the example shown in FIG. 1A, the first interconnect layer 104 of the interconnect structure, i.e. the layer closest to the substrate 101, corresponds to a horizontal metallization level MX. In the example shown, this metallization level MX comprises a conductive track 105 made in a trench, i.e. a through recess formed in the dielectric material, which in this case extends in the longitudinal direction X. Where applicable, this conductive track 105 may be connected electrically to one or more active components formed in the active zone of the substrate 101 of the device 100. More generally, the horizontal metallizations formed in the metallization level MX of the first layer 104 have the function of connecting together elements of the active components produced in the active zone of the substrate 101. For this purpose, they are coupled to them by vias (not shown). These vias pass through the insulating layer 102 which is directly below the layer 104 and the passivation layer 103 which separates the two layers of dielectric material 102 and 104.

The last layer 110 of the interconnect structure shown in FIG. 1A, which corresponds to the metallization level HBM, comprises metal bonding pads the function of which is to ensure hybrid bonding of the wafer 100 to another wafer 200. More specifically, it comprises bonding pads of a first type 111a, and bonding pads of a second type 111b. All of these pads serve to bond the microelectronic device corresponding to the wafer 100, by hybrid bonding, to another microelectronic device corresponding to the wafer 200. Structurally, these two types of pads are identical, and they are made from the same metal, namely copper in the example, and in the same way by implementing the Damascene process. The difference between these two types of pads is simply functional.

To be specific, on the one hand, the bonding pads 111a of the first type serve only, i.e. exclusively, as bonding support for the hybrid bonding of the wafer 100 to the other wafer 200, as shown in FIG. 1B, interacting with corresponding bonding pads 211a of said other wafer 200. Thus, the bonding pads 111a of the first type will also be called “purely bonding pads” below or “non-functional pads”, as they do not play any role in the operational functioning of the integrated circuit.

On the other hand, the bonding pads 111b of the second type serve not only for bonding together the two wafers 100 and 200, like the purely bonding pads 111a, but also serve for electrical connection between said wafers, interacting with corresponding pads 211b of the other wafer 200. Below, the bonding pads 111b of the second type are called “bonding and electrical connection pads” or “functional pads” because they play a role in the operational functioning of the integrated circuit by ensuring the passage of electrical signals from one wafer to the other.

Lastly, the penultimate layer 107 of the interconnect structure of FIG. 1A, in other words the interconnect layer directly below the top interconnect layer 110, which corresponds to the metallization level HBV, comprises vias 108. These vias 108 are vertical metallization elements adapted to produce electrical coupling between a functional bonding pad of the metallization level HBM in the top interconnect layer 110, on the one hand, and a metallization element of the metallization level MX in the bottom interconnect layer 104, on the other hand.

In the example shown in FIG. 1C, such vias 108 are produced in electrical continuity with the bonding and electrical connection pads 111b of the wafer 100 in the metallization level HBM formed directly above the metallization level HBV, and also in electrical continuity with the conductive track 105 in the metallization level MX below the metallization level HBV. The vias 108 have the function of electrically connecting the metallization elements to which they are respectively coupled, in other words with which they are in electrical continuity. Where applicable, such vias 108 may ensure the electrical continuity of bonding pads of the second type 111b directly with metallization elements distributed in metallization layers even lower than the layer 104 in FIG. 1A in the stack of n interconnect layers, and even directly with active elements produced in the active zone of the substrate 101. These vias 108 may pass through one (or more) intermediate layer(s) of dielectric material based on silicon dioxide (SiO2) before reaching a horizontal metallization in an interconnect layer corresponding to a horizontal metallization level located lower down in the stack, or an active element of the active zone of the substrate 101.

To be specific, as will be appreciated by those skilled in the art, several horizontal metallization levels such as the metallization level MX may be formed in respective interconnect layers which are produced in a stack before forming the penultimate layer 107 and the last layer 110 of the interconnect structure, which correspond to the levels HBV and HBM, respectively. Where applicable, the horizontal metallizations formed in these respective interconnect layers may be connected to one another by vertical metallizations, i.e. by vias which are made in dedicated interconnect layers corresponding to respective vertical metallization levels, interspersed between the corresponding horizontal interconnect layers.

FIG. 1B symbolically illustrates the hybrid bonding of the wafer 100 of FIG. 1A to the other wafer 200. This may be hybrid bonding at wafer level, in other words W2W bonding, but it may also be D2W hybrid bonding or even D2D hybrid bonding. FIG. 1C shows the 3D microstructure obtained by this vertical assembly. As symbolically shown by an arrow, the top wafer 100 is turned over vertically, and its position is adjusted in the horizontal plane XY (that is to say it is aligned both in the longitudinal direction X and in the transverse direction Y) relative to the bottom wafer 200. This result is obtained by referencing its bonding pads 111a of the first type and its bonding pads of the second type 111b, with the corresponding bonding pads of the bottom wafer 200. This operation is carried out according to techniques and using equipment that are known to those skilled in the art, and an explanation of which would exceed the scope of the present description. The bonding of the top wafer 100 to the bottom wafer 200, as shown in FIG. 1B, is obtained by the effect of Van der Waals forces, covalent bonds and hydrogen bonds implemented when they are placed in contact, thanks to the particularly smooth and flat surface finish of the respective top sides of the wafers 100 and 200.

FIG. 1D is a top view of a 3D microstructure obtained by a vertical integration method according to the prior art presented above. This microstructure may correspond to the microstructure shown in FIG. 1C, or to any structurally comparable microstructure. With reference to FIG. 1D, there are:
metal lines 205 made in the metallization level MX of the interconnect structure of the bottom wafer 200;
a metal line 105, which is depicted here as slightly transparent to show what is underneath, and which is made in the metallization level MX of the interconnect structure of the top wafer 100;
the bonding pads 111a and 111b of the top wafer 100, which comprise purely bonding pads or pads of the first type 111a, and bonding and electrical connection pads or pads of the second type 111b (which are surrounded by circles in dotted lines in the figure, so as to distinguish them more clearly). These bonding pads 111a and 111b coincide spatially, in the horizontal plane XY, with the corresponding bonding pads of the bottom wafer 200 in the top view of FIG. 1D, in line with the assumption of perfect horizontal alignment between the two wafers 100 and 200. In other words, the bonding pads 111a and 111b of the top wafer 100 are perfectly aligned in the direction X and in the direction Y with the corresponding bonding pads 211a and 211b (see FIG. 1C) of the bottom wafer 200. Consequently, they conceal the latter in a direction of viewing along the vertical direction Z, from top to bottom. The bonding pads 211a and 211b (see FIG. 1C) of the bottom wafer 200 are therefore not visible in FIG. 1D;
the vias 108 which are produced in the metallization level HBV of the interconnect structure of the top wafer 100 and which are represented by small squares in the bonding and connection pads 111b. Also in this case, and again in line with the assumption of perfect horizontal alignment between the two wafers 100 and 200, the vias 108 of the top wafer 100 conceal the corresponding vias 208 of the bottom wafer 200. In the example shown, there are four vias of square section for connecting a pair of bonding pads 108 and 208, in order to allow the passage of a current which is four times higher than with a single via of identical section. The number and the shape of the section of the vias may vary from one application to the next. For example, vias of rectangular, circular or elliptical section may be preferred. A number of vias lower than 4, for example a single via of relatively larger section, may also be provided instead of the four vias of relatively smaller section that are shown in the example of FIG. 1D.

In FIG. 1D, the bonding pitch defined as the spacing, in other words the centre-to-centre distance, between two adjacent bonding pads (whether of the first type 111a or of the second type 111b), both in the direction X and in the direction Y, is denoted by the letter “P”. As can be seen in the figure which shows an embodiment in accordance with the prior art, but as is also the case for an embodiment implementing the invention, the bonding pads 111a and 111b are present with a relatively high density, reflected in a bonding pitch P which is below a predetermined threshold. This threshold is lower than or equal to 10 micrometres (μm), for example of the order of around 5 μm. Furthermore, their distribution on the surface of the wafer 100 is substantially uniform, for the reasons mentioned above. These constraints are generally specified in the applicable DRM, to which the designer of the electronic circuit in question can refer.

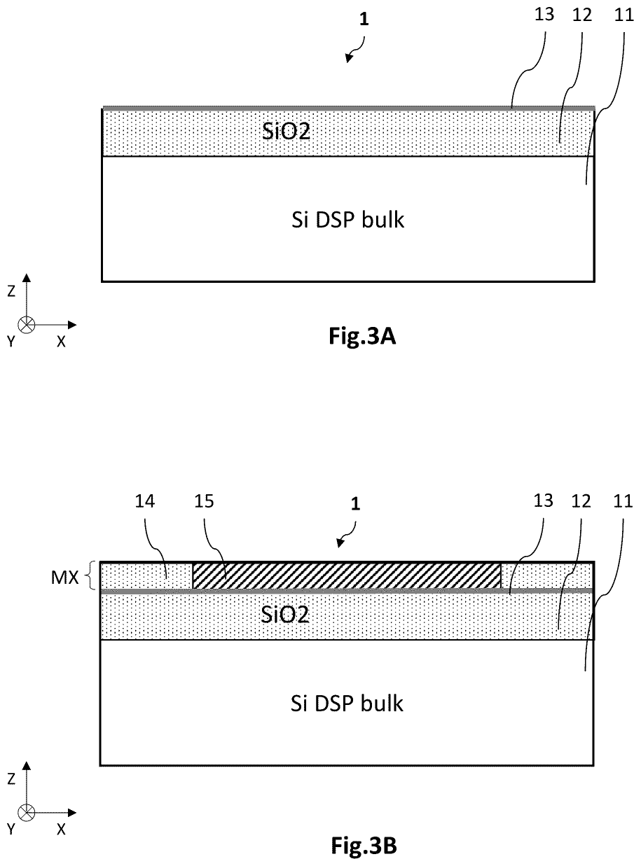

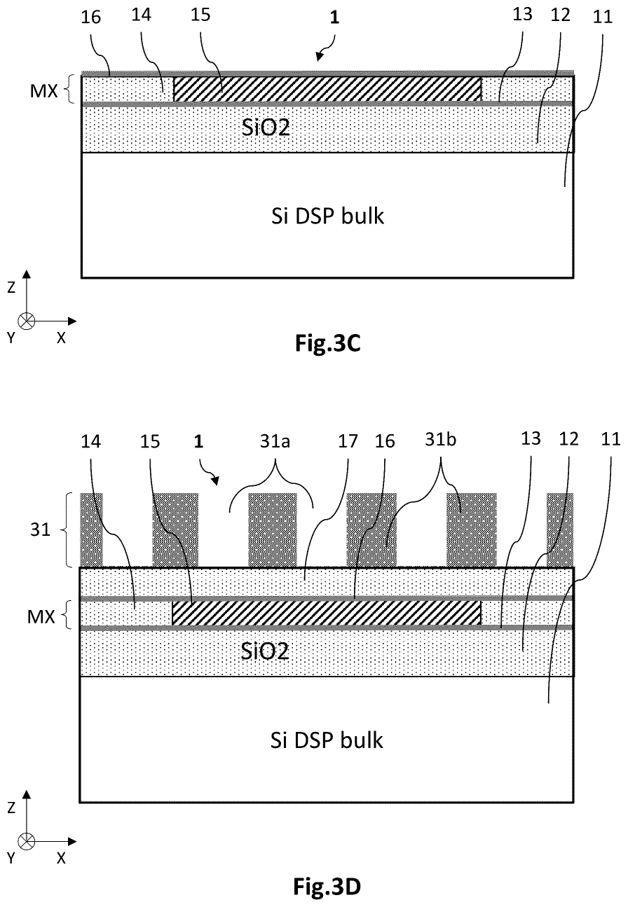

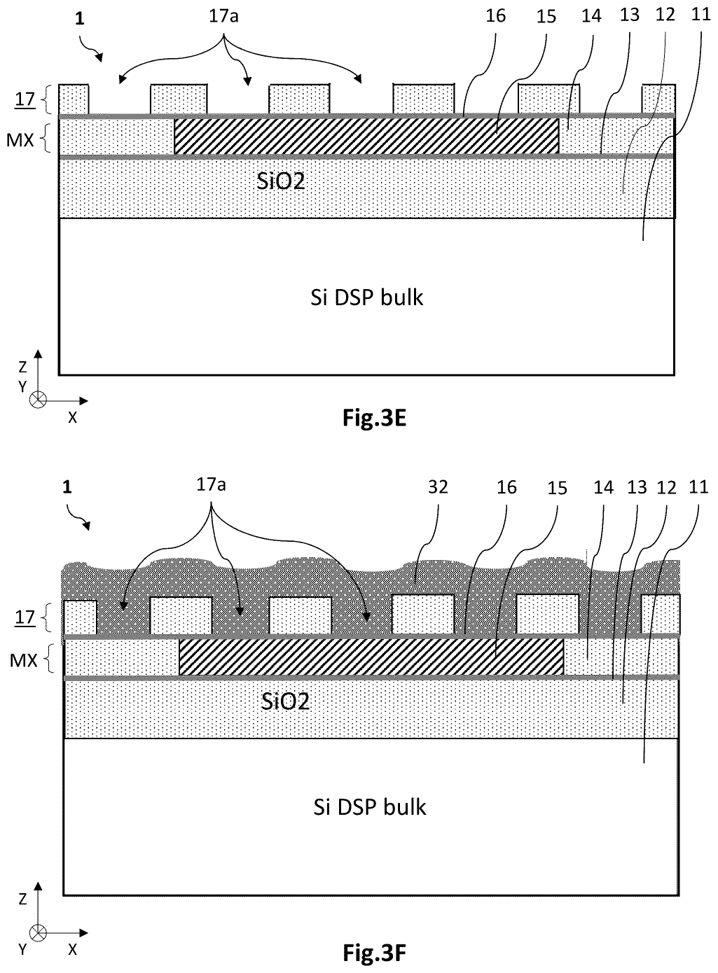

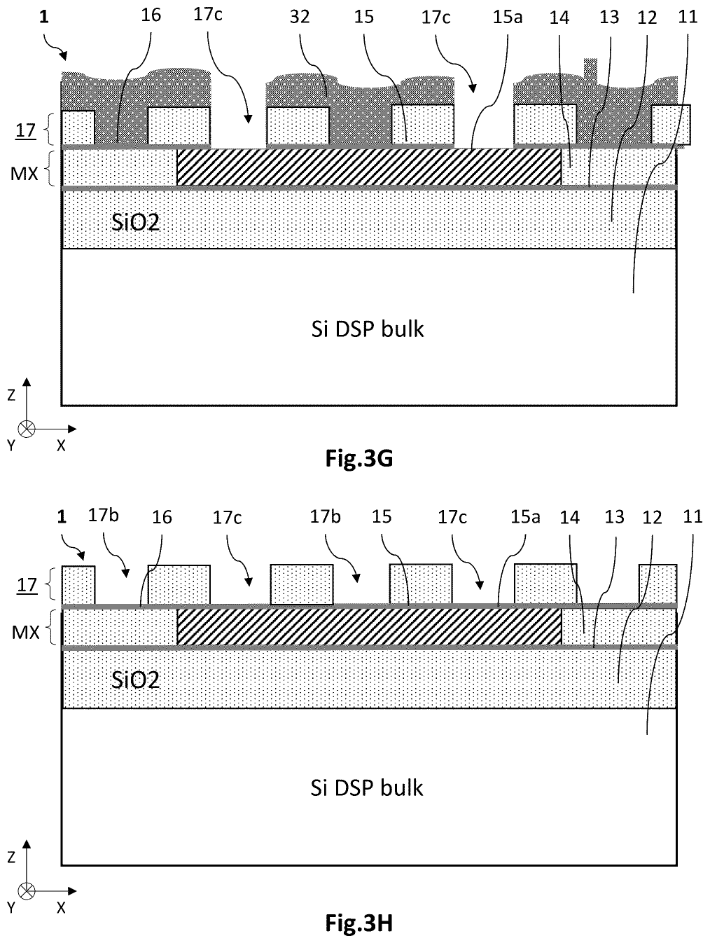

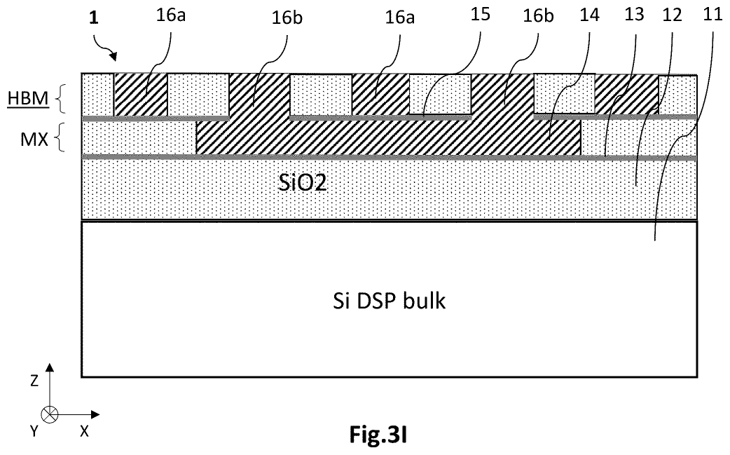

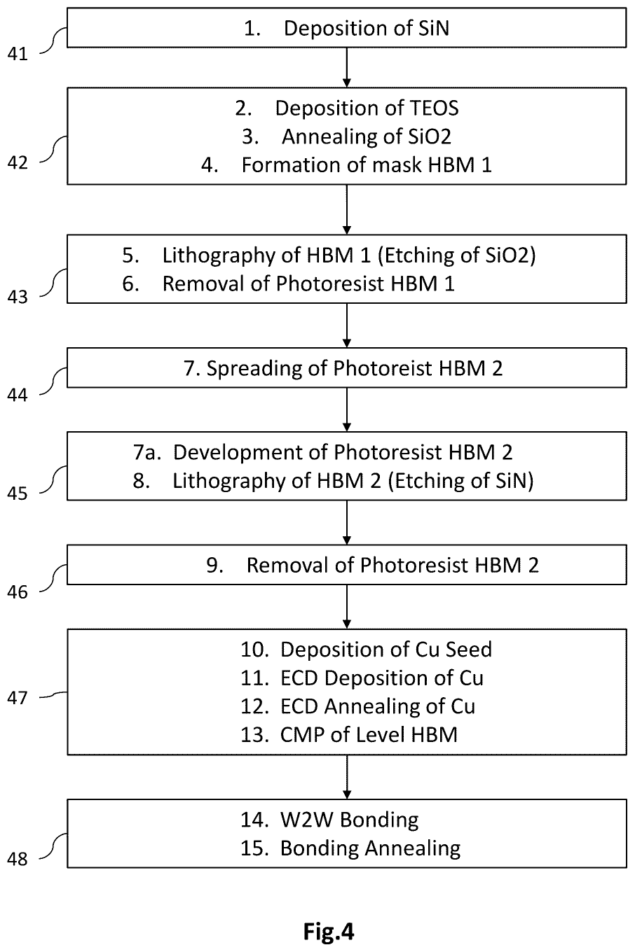

An example of the implementation of the method for producing a 3D microstructure by vertical integration of two separate wafers 1 and 2 in accordance with the invention will now be described with reference to the block diagram of FIG. 4. Implementation of the method makes it possible to produce the example of a 3D microstructure shown in FIG. 2, comprising the top wafer 1 turned over and bonded on the bottom wafer 2. In this description, reference will also be made to the views in section in FIG. 3A to FIG. 3I. These figures show one of the wafers in the process of production, and specifically the top wafer 1, after implementation of predetermined steps or groups of steps of the method for said wafer 1 individually, before hybrid bonding of the two wafers 1 and 2. Note that, in the highly simplified example considered herein, the production of the bottom wafer 2 of the 3D microstructure is identical or comparable to the production of the top wafer 1, which will therefore be the only one described here to avoid pointless repetition in the present description. Moreover, and again for the sake of simplification, the respective metallization structures of the top wafer 1 and the bottom wafer 2 shown are structurally identical to one another. However this is purely a non-limiting example.

FIG. 2 shows the 3D microstructure resulting from the hybrid bonding of the wafer 1, provided with an original interconnect structure obtained by implementing the method according to the second aspect of the invention, on another wafer 2 (or bottom wafer) having an interconnect structure obtained in a similar manner.

The 3D microstructure of FIG. 2 contains a first microelectronic device produced on a top wafer 1, and a second microelectronic device produced on a bottom wafer 2 on which the top wafer 1 is bonded by hybrid bonding after being turned over vertically. The bottom wafer 2 and the top wafer 1 each comprise a substantially flat substrate, 21 and 11 respectively, and an interconnect structure formed on top of said substrate.

The respective interconnect structure of each of the top 1 and bottom 2 wafers is a vertical stack of at least two superimposed interconnect levels each comprising a hybrid layer essentially composed of a dielectric material, namely, respectively:
an upper interconnect level (HBM) with metal bonding pads 17b and 17c, formed in the dielectric material and adapted to interact with corresponding metal bonding pads 27b and 27c, respectively in the other wafer 2 for hybrid bonding of the top wafer 1 on the bottom wafer 2; and
a horizontal interconnect level (MX) which is directly below the upper interconnect level HBM, with horizontal metallization elements 15 and 25.

The adverb “essentially”, used above with reference to the composition of the hybrid layer of each of the levels HBM and MX, must be understood as meaning that one and/or the other of these levels may include in addition, and for example, a passivation layer provided to passivate the dielectric material included in the composition of said level. Furthermore, the expression “directly below” used above in relation to the horizontal interconnect level MX, must be understood as meaning that there is no other interconnect level between the level HBM and said level MX, and therefore no vertical interconnect level. In other words, as those skilled in the art will appreciate, this means that the first metallization level (in this case, the level MX) which comes below the hybrid bonding level HBM in the stack of interconnect levels, is a horizontal metallization level and not a vertical metallization level. However, this does not prevent the horizontal interconnect level MX from including, on top of said level and therefore below the metallization level HBM, a passivation layer, for example a layer of silicon nitride (SiN) as will be described below. In other words, this does not mean that all the dielectric portions and/or all the metal portions of the level HBM are directly in contact with dielectric portions and/or metal portions of the level MX.

The metal bonding pads 17b, 17c and 27b, 27c of each of the top 1 and bottom 2 wafers, respectively, are distributed substantially homogeneously on the top surface of the upper interconnect level HBM of the interconnect structure of said wafer. They are also produced with a bonding pitch, defined as the maximum spacing between adjacent bonding pads horizontally in the plane of said top surface, which is below a predetermined associated threshold. This threshold may be lower than or equal to 10 μm, which provides a high interconnect density between the two wafers 1 and 2 by means of the bonding pads. Preferably, it may be of the order of 5 μm, for example.

The respective metal bonding pads 17b, 17c and 27b, 27c of each of the top 1 and bottom 2 wafers comprise respective bonding pads 17b and 27b of a first type, which are electrically insulated from any horizontal metallization element such as the metallizations 15 and 25, respectively, in the horizontal interconnect level MX of the interconnect structure of said wafer. Moreover, the respective metal bonding pads 17b, 17c and 27b, 27c of each of the top 1 and bottom 2 wafers further comprise bonding pads 17c and 27c respectively of a second type, which are each electrically coupled to at least one underlying horizontal metallization element, formed in the horizontal metallization level MX of the interconnect structure of said wafer.

In other words, the interconnect structure of each of the top 1 and bottom 2 wafers of the microstructure of FIG. 2 does not include a vertical metallization level directly below the level HBM, unlike the 3D microstructure of FIG. 1D according to the prior art, described above, which has such a vertical metallization level, namely the level HBV. Instead, the bonding pads of the second type 17c or 27c, respectively, of the metallization level HBM of the interconnect structure of each of the wafers 1 and 2 ensure electrical connection of said wafer to the other wafer. This dispenses with a metallization level in each of the wafers 1 and 2 and therefore two metallization levels for the 3D microstructure formed by these two stacked wafers. For each of these levels, a layer of insulating material (for example SiO2) and its associated passivation layer (for example SiN) are thus avoided. This reduces the level of stress on the 3D microstructure since this stress depends on the number of layers in the interconnect structures of the wafers. Naturally, the costs and thermal budgets, water, etc. for producing the individual 2D semiconductor devices, which are each produced on one of the wafers 1 and 2, are also reduced.

In some embodiments, the horizontal interconnect level MX of the interconnect structure of each of the bottom 1 and top 2 wafers comprises a passivation film 16 or 26, respectively, made of electrically insulating material, and covering the layer of dielectric material of said horizontal metallization level MX. The bonding pads of the first type 17b and 27b of each of the top 1 and bottom 2 wafers, respectively, are thus electrically insulated from any horizontal metallization element in the horizontal interconnect level MX located underneath in the interconnect structure of said wafer, at least by the insulating material of this passivation film 16 or 26 covering the layer of dielectric material of said horizontal metallization level MX.

In some embodiments, the layer 17 or 27 of dielectric material of the upper interconnect level HBM of the interconnect structure of each of the wafers 1 and 2, respectively, is a hybrid layer of dielectric material with patterns, said patterns defining:
solid zones 17a or 27a of said dielectric material, in other words zones of the layer 17 or 27 which have not been etched;
first vertical through holes 17b or 27b, filled with metal and at which the insulating material of the passivation layer of the horizontal interconnect level MX is present. These first through holes, once filled with metal, form the bonding pads of the first type (also designated below using the references 17b and 27b) of the upper interconnect level HBM of the wafer; and
second vertical through holes 17c or 27c, filled with metal, and at which the passivation layer 16 or 26 of the horizontal interconnect level MX has an opening because the silicon nitride (SiN) of said passivation layer 16 or 26, respectively, has been removed by etching. These second through holes, once filled with metal, form the bonding pads of the second type (also designated below using the references 17c and 27c) of the upper interconnect level HBM of the wafer. They are each in electrical continuity with one of the horizontal metallization elements 15 or 25 of the horizontal interconnect level MX of the wafer 1 or 2, respectively, through the opening in the passivation layer 16 or 26, respectively, of said horizontal interconnect level MX.

As will be appreciated by those skilled in the art, it is therefore the passivation layer 16 of the metallization level MX which, according to the openings made or not made in said layer, and more specifically in line with the holes 17c and 17b made in the layer 17 corresponding to the upper metallization level HBM for receiving the metal of the functional bonding pads 17c or the non-functional bonding pads 17b, respectively, that makes it possible to differentiate between the function of said functional bonding pads 17c and the function of the non-functional bonding pads 17b. To be specific, the silicon nitride (SiN) of the passivation layer, when still present, prevents electrical continuity between the bonding pad in question in the metallization level HBM and any metallization element in the horizontal metallization level MX directly below said level HBM.

In some embodiments, the dielectric material of the hybrid interconnect layers of the interconnect structure of each of the top 1 and bottom 2 wafers is silicon dioxide (SiO2). The material constituting the metal bonding pads 17b, 17c and 27b, 27c of the upper interconnect level HBM and/or the material constituting the horizontal metallizations 15 and 25 of the horizontal interconnect level MX of the interconnect structure of the wafers 1 and 2, respectively, may be copper (Cu) or an alloy based on copper. Lastly, the electrically insulating material of the passivation film 16 or 26 of the horizontal interconnect layer (MX) of the interconnect structure of each of the wafers 1 and 2 may be a nitride, such as silicon nitride (SiN) or another dielectric, for example a carbon derivative of a nitride such as silicon carbonitride (SiCN).

Thus, after vertical turning over and bonding of the wafer 1 on the wafer 2 making a possible to form the microstructure shown in FIG. 2, the bonding interface 60 is a hybrid interface. To be specific, it comprises:
an SiO2/SiO2 interface at the facing zones 17a and 27a; and
a Cu/Cu interface at the facing non-functional bonding pads 17b and 27b, and at the facing functional bonding pads 17c and 27c.

The substrate 11 of the top wafer 1 and/or the substrate 21 of the bottom wafer 2 may each comprise an active zone with active elements, in the upper part of said substrate. In this case:
the non-functional bonding pads 17b and 27b of the interconnect structure of each of the wafers 1 and 2 are electrically insulated from the active elements of the active zone of the substrate 11 or 21, respectively, of said wafer; whereas
at least some of the functional bonding pads 17c and 27c of the interconnect structure of the top wafer 1 and/or of the bottom wafer 2 are electrically coupled to at least one of the active elements of the active zone of the substrate 11 or 21, respectively, of said wafer.

Embodiments of a method for producing the 3D microstructure in FIG. 2 as presented above will now be described. This method comprises fifteen essential technological steps, which will be referred to below by the numbers 1 to 15. Some of these steps are grouped together in certain blocks of the block diagram in FIG. 4, purely with the aim of streamlining the description set out below. Specifically, the figures showing the microstructure in the course of production only depict the wafer at the end of each group of steps in question, when it would not make the description in any way clearer if they were depicted individually at the end of each step of the group.

As stated in the introduction, the method is essentially implemented during the BEOL phase of fabrication of each wafer individually, the wafers then being assembled vertically together by hybrid bonding. More specifically, the method proposes an alternative to the production of the penultimate layer and the last layer of the interconnect structure which correspond to the metallization level HBV (vertical interconnection) and to the metallization level HBM, respectively, of a wafer according to the prior art, as presented above with reference to FIG. 1A. These two layers are replaced, according to the invention, by a single bonding layer which alone performs the respective functions of the respective metallization levels HBV and HBM of two wafers assembled vertically according to the prior art. As will be recalled, in the interconnect structure according to the prior art, the last layer (metallization level HBM) is the layer in which the bonding pads are made (non-functional pads and functional pads) for hybrid bonding, while the penultimate layer (vertical metallization level HBV) is the layer in which are made the vias that vertically interconnect the functional bonding pads (and only these bonding pads, not the non-functional bonding pads) to horizontal metallizations made in one or more metallization levels lower down in the interconnect structure, and/or to active elements made in the active zone of the underlying substrate.

At the end of the FEOL phase of fabrication of the wafer 1, which precedes the BEOL phase, said wafer is as shown in FIG. 3A. The wafer 1 comprises the substrate 11 which is covered with a layer of insulating material 12, itself covered with a passivation layer 13.

The substrate 11 is for example a bulk silicon (Si bulk) substrate. In the upper part, under the insulating layer 12, the substrate 11 comprises active components, not shown, such as transistors or photodiodes. These elements are made, for example in CMOS technology, during the FEOL phase of fabrication of the wafer 1. The low resistivity of a bulk silicon substrate is advantageous for latch-up of these MOS transistors. In one example, the substrate 11 is a DSP (Double Side Polished) substrate, which has the advantage of being directly usable thanks to the surface finish of its top and bottom sides, which are highly polished.

The electrically insulating (dielectric) material of the insulating layer 12 may be silicon dioxide (SiO2), for example. Thin layers of silicon dioxide develop spontaneously on the silicon wafers, by thermal oxidation, producing a very thin layer of around 1 nm of native oxide. The layer 12 may thus be obtained by growing a silicon dioxide layer from this thin native oxide layer, for example by heating the wafer to temperatures of between 600 and 1200° C., in the presence of oxygen (dry oxidation) or water (wet oxidation), according to one or other of the following chemical reactions, respectively:

Si+O2->SiO2; or

Si+2H2O->SiO2+2H2.

Wet oxidation has a more rapid growth rate but the SiO2 layer obtained is less dense than a layer obtained by dry oxidation.

The passivation layer 13 is for example a layer of silicon nitride (SiN). It has the function of stabilizing the state of the insulating layer 102 after production of said layer, and preventing contamination of the active zone of the substrate, notably by diffusion of copper or water. The layer 13 of silicon nitride may be deposited by low-pressure chemical vapour deposition (LPCVD) or by plasma-enhanced chemical vapour deposition (PECVD), then chemically treated using phosphoric acid (H3PO4). The production of the passivation layer 13 ends the FEOL phase of fabrication. The steps of fabrication that follow belong to the BEOL phase of fabrication.

The BEOL phase of fabrication begins with the production of the first metallization level of the interconnect structure which is produced on the front side (top side) of the wafer 1. With reference to FIG. 3B, in the very simplified example shown in this figure, the interconnect structure only comprises one metallization level MX specifically for the formation of horizontal metallizations in a layer 14 of dielectric material. The reference 15 designates such a horizontal metallization, which is for example a conductive track extending in the horizontal plane XY, in this case in the longitudinal direction X, for example so as to electrically connect together the active elements (not shown) produced in the active layer of the underlying substrate 11.

Naturally, the invention is not limited either by the number of metallization levels formed by respective stacked interconnect layers for containing horizontal metallizations such as the metal track 15, or by the number or configuration of said tracks, or indeed by their function in the electronic circuit concerned. It may notably be a question of conductive tracks for electrical connection between various active elements but also passive elements such inductances, capacitors etc. made in the form of copper patterns extending in one or more corresponding metallization levels of the interconnect structure. Where applicable, horizontal metallizations made in respective horizontal metallization levels may be electrically connected together by vertical metallizations, in other words vias. These vias are made in vertical metallization levels interspersed between the corresponding horizontal metallization levels.

The metallizations in the metallization level MX have an average dimension in the horizontal plane XY of between a few dozen nanometres and a few dozen microns, for example between 20 nm and 20 μm, preferably between 200 nm and 10 μm, and more preferably between 800 nm and 5 μm, for example of the order of 1 μm or 2 μm.

The method according to embodiments comprises steps for bonding of the wafer 1, as top wafer for example, to another wafer 2 which is then a bottom wafer in this example, after vertically turning over and hybrid bonding of said top wafer 1 on said bottom wafer 2. By this bonding, the top and bottom wafers are mechanically connected owing to the effect of Van der Waals forces and at the same time electrically connected to one another by non-functional bonding pads (purely bonding pads) and by functional bonding pads (bonding and electrical connection pads), respectively. According to embodiments of implementation, the bonding structure which provides this double function only comprises a single metallization level, denoted HBM (Hybrid Bonding Metal), instead of both the horizontal metallization level HBM and the vertical metallization level HBV provided for in the prior art and as shown in FIGS. 1A-1D described above, in which the HBV level comprises vias that provide for the electrical connection of the functional bonding pads to the horizontal metallizations formed in the horizontal metallization layers lower down.

In a first step (step 1), represented by block 41 of the diagram in FIG. 4, a passivation layer 16 is formed on top of the layer 14 corresponding, where applicable (in other words where there are several metallization levels stacked vertically), to the uppermost horizontal metallization level MX, in which horizontal metallizations for interconnection of the active components and/or passive components of the electronic circuit are made. The result of step 1 is shown in FIG. 3C.

The passivation layer 16 is for example a layer of silicon nitride (SiN) or silicon carbonitride (SiCN). It makes it possible to stabilize the state of the silicon dioxide (SiO2) in the metallization level MX, in other words to significantly slow down its corrosion rate, in other words its natural oxidation rate, and to prevent the formation of scratches on the surface of the copper conductive tracks. It also makes it possible to protect the metallizations such as the conductive track 15 against micro scratches during handling of the wafer from one processing station to another in the clean room. A thin layer of silicon nitride 16 (of the order of 200 nm, for example) may be formed by chemical vapour deposition (CVD) involving mixtures of gases such as Si/NH4, SiCl4/NH3 or SiH2Cl2/NH3, and chemical treatment with phosphoric acid (H3PO4). The CVD may be low-pressure chemical vapour deposition (LPCVD) which is carried out at a relatively high temperature (between 700 and 900° C., of the order of 775° C., for example). As a variant, the passivation layer 16 of silicon nitride may be formed by plasma-enhanced chemical vapour deposition (PECVD), which is carried out at a relatively moderate temperature (between 200 and 350° C., of the order of 200° C., for example) and under vacuum. In one example, the silicon nitride layer 16 may have a thickness of around 50 nm.

With reference to FIG. 4, a group 42 of subsequent steps is then implemented, so as to end up with the microstructure shown in FIG. 3D. The steps in this group of steps 42 comprise steps 2, 3 and 4 of the method, which are implemented successively and in this order.

In step 2 of the method, a layer 17 of TEOS (short for tetraethyl orthosilicate) is deposited conformally on the top face of the microstructure of FIG. 3C. TEOS has the chemical formula Si(OCH2CH3)4 or more simply Si(OEt)4, and is used as silicon dioxide (SiO2) seed.

In step 3 of the method, annealing is carried out, in other words the microstructure covered with the TEOS conformal layer is heated to a temperature of for example around 400° C., to convert the TEOS layer 17 into a layer of silicon dioxide (SiO2). In one example, the layer 17 of silicon dioxide thus formed may have a thickness of around 900 nm. This layer 17 acts as electrical insulation. To be specific, it can block the electrical current from or to the metallizations made in the underlying layer 14 of the interconnect structure.

Those skilled in the art will appreciate that there are other ways of producing the dielectric layer 17, but the layer obtained as proposed above (with steps 2 and 3 above) has the advantage of considerable chemical stability.

In step 4, a photoresist resin mask 31 is formed, in order to obtain a protective covering on the surface of the microstructure, for the purpose of carrying out a first photolithographic operation 5 (denoted “HBM 1” in FIG. 4 and below), to be performed so as to produce the metallization level HBM with non-functional bonding pads 17b and functional bonding pads 17c for hybrid bonding. This photolithography HBM 1 has the purpose of creating a mask by etching of the silicon dioxide layer 17 through the photoresist mask 31, which mask may then be used to open up the layer of silicon nitride 16 in order to expose the portions of the metallizations of the layer MX intended to be connected electrically to the functional bonding pads 17c.

More specifically, step 4 comprises:
spreading the photoresist, for example by spin coating, the principle of which consists in spreading on the wafer, using centrifugal forces, a small amount of resin mixed with a solvent which temporarily gives it a degree of fluidity, and placed in the centre of the wafer before it is rotated; followed by the development of the photoresist which includes
exposing said resin to optical radiation, for example ultraviolet (UV) radiation, through an ad hoc optical mask. Such a mask comprises opaque zones and transparent zones, which define the etching patterns, either positive or negative depending on the nature of the photoresist in question. This makes it possible to define the patterns to be reproduced on the wafer 1, in the SiO2 layer 17, by etching through the resin layer thus developed which forms an etching mask; and
selectively removing, for example by chemical etching, exposed portions of resin, or conversely non-exposed portions of resin, depending on the nature (positive or negative) of the photoresist. The removal method implemented may be vapour phase chemical etching, for example under oxygen plasma, which makes it possible to clean off very thoroughly any trace of organic materials such as the photoresists.

The optical mask used to reveal the photoresist of the layer 31 in step 4 has patterns corresponding to the scheme for implantation of the bonding pads for hybrid bonding, including the non-functional bonding pads 17c and functional bonding pads 17b. In other words, the first lithography HBM 1 makes it possible to form, in the layer 17 of dielectric material, the wells 17a in which all of the metal bonding pads for hybrid bonding of the wafer 1 on the other wafer 2 will then be produced, whether functional or non-functional, in other words whether they serve only for bonding or both for bonding and electrical connection, respectively, between the two wafers 1 and 2.

There is no need to describe in more detail the above sub-steps of step 4 for obtaining the photolithography mask HBM 1 (also abbreviated to mask HBM 1), which are well known per se to those skilled in the art.

On completion of the group of steps 42 comprising steps 2, 3 and 4 presented above, the photoresist mask 31 is as shown in FIG. 3D mentioned above. In the configuration of FIG. 3D, the mask HBM 1 exposes the layer 17 only through its open zones 31a (or openings), and masks the layer 17 away from said zones 31a.

In step 5, which forms part of the group of steps 5 and 6 represented by block 43 of the diagram in FIG. 4, the layer 17 of dielectric material (SiO2) is etched through the mask HBM 1, with an etch stop on the layer 16 of silicon nitride.

This may be chemical etching (or wet etching) using a solution based on hydrofluoric (HF) acid for example, or physical etching (or dry etching), in other words plasma etching. The etching may also be reactive ion etching (RIE), which is a variation of plasma etching combining the selectivity of chemical etching and the anisotropy of physical etching. In some implementation embodiments, the plasma may be a fluorocarbon plasma, based on a gas such as carbon tetrafluoride (CF4) for example, or based on sulphur hexafluoride (SF6) or based on nitrogen trifluoride (NF3), or any combination of these gases. The layer 17 of insulating material, partially protected by the etching mask HBM 1 formed by the layer 31 of silicon dioxide which is partially opened up as explained above, is placed in a chamber which is placed under vacuum. This chamber has two horizontal and parallel electrodes, the lower electrode serving as plate for receiving the wafer 1. Once the vacuum has been created in the chamber, the gas is introduced therein. Next, a strong radiofrequency (RF) electric field, for example of around 100 volts per metre or more, is applied to the lower electrode. This generates, in the chamber, a plasma, in other words a partially ionized gas. To be specific, some of the electrons in the molecules of gas are drawn off by the electric field, which ionizes said molecules. The top face of the wafer is then bombarded with ions which breaks it up.

The advantage of such etching is that it is highly anisotropic, the ion bombardment being carried out only in the direction between the electrodes, in other words the direction normal to the plane of the wafer 1. The border between the etched zones and non-etched zones is therefore very straight and vertical. However, this etching is not very selective, in other words it destroys the material of the mask HBM 1 formed by the layer 31 at the same time as the zones of the underlying protective layer 17 which are exposed by the opening 31a through said mask. Etching is completed when the silicon nitride (SiN) of the layer 16 is reached in the openings 31a of the mask HBM 1.

Step 6 consists of stripping away the residues of resin from the mask HBM 1. This can be carried out by chemical etching, for example using a solution based on sulphuric acid (H2SO4) and hydrogen peroxide (H2O2).

Note that even if the step of etching 5 leaves the surface of the mask HBM 1 relatively damaged, this is not really a disadvantage since, in step 6 which follows completion of etching, the residues from the etching mask HBM 1 are removed. To limit the risk of the mask being destroyed before the end of etching, ion bombardment may be temporarily interrupted in step 5 during etching, for annealing of the wafer in order to re-harden the mask HBM 1 by re-forming the crystalline network of the layer 31, before recommencing etching by ion bombardment. This process may optionally be repeated several times subsequently, until etching is completed, in other words until the silicon nitride layer 16 is reached.

Upon termination of the group of steps 43 comprising steps 5 and 6 described above, the microstructure is as shown in FIG. 3E.

In step 7, which is the only step in block 44 of the diagram of FIG. 4, a new photoresist layer 32 is spread in order to form an etching mask, so as to carry out a second lithography denoted HBM 2. With reference to FIG. 3F, the photoresist layer 32 is deposited conformally on the front side of the wafer, for example by spin coating (see above, in relation to the photoresist layer 31 for forming the etching mask HBM 1). Thus, as can be seen in this figure, the layer 32 matches the relief resulting from the openings 17a formed in the layer of dielectric material 17 by the first lithography HBM 1. In other words, said layer 17 has a thickness such that the free face of this layer conformally follows the hollows and/or protrusions on the microstructure on which it is deposited.

The photoresist of the layer 32 is then developed in step 7a to form a new etching mask, which is then used to carry out a second lithography, referred to as HBM 2. This lithography HBM 2 is then carried out in step 8 to etch the layer 16 of silicon nitride. Below and in the figures of the drawings, this mask is abbreviated to “mask HBM 2”.

In the block diagram of FIG. 4, steps 7a and 8 are grouped together in block 45 because the overall result obtained after carrying out these two steps is shown in FIG. 3G.

As shown in this figure, the optical mask used to reveal the photoresist of layer 32 in step 7a has patterns corresponding to the scheme for implantation of the functional bonding pads 17c. In other words, the optical mask used to reveal the photoresist of layer 32 in step 7a has patterns corresponding to the interconnect patterns defined by the scheme for implantation of the functional bonding pads 17c which are intended for the electrical connection of the wafer 1 to the other wafer 2, by hybrid bonding of said wafers 1 and 2. In other words, again, the second lithography HBM 2 makes it possible to open up the bottom of certain wells 17c out of the wells 17a that were formed in the layer 17 of dielectric material by the first lithography HBM 1.

This result is obtained in step 8 by partially etching the layer of silicon nitride 16 at the bottom of said wells 17c only, through the etching mask HBM 2. By means of this partial opening of the layer 16 in the etching step 8, at the bottom of the wells 17c the metal of certain horizontal metallizations of the metallization level MX in the dielectric layer 14 is exposed, such as the conductive track 15 in the example shown in FIG. 3G. As will be appreciated, these are metallizations which, according to the routing map for the 3D microelectronic device, need to be linked with the bonding interface between the wafers 1 and 2. The functional bonding pads at 17c may then be formed by filling the wells 17c with metal, with coupling, in other words with electrical continuity, as far as horizontal metallizations in the metallization level MX, in order to provide the electrical connection desired between the two wafers 1 and 2. Of course, as well as providing this electrical connection, the functional pads 17c thus produced may serve as support for hybrid bonding of said wafers.

The other wells 17b out of the wells 17a formed by the first lithography HBM 1, i.e. wells other than the wells 17c mentioned above, are not opened up as far as the metal of the hybrid layer 14 by the etching 8 corresponding to the second lithography HBM 2. The layer of silicon nitride 16 there is left intact, being protected by the etching mask HBM 2. These other wells 17b are the wells in which the non-functional bonding pads will subsequently be produced by deposition of metal, without coupling, in other words without electrical continuity with the metal of the horizontal metallizations in the metallization level MX. The electrical insulation between the non-functional bonding pads 17b and any horizontal metallization in the metallization level MX in the hybrid layer 14 is ensured by the layer of silicon nitride 16 (insulating material) which remains intact at the bottom of the wells 17b following the etching carried out in step 8 through the etching mask HBM 2.

The etching of the silicon nitride of the layer 16 carried out in step 8 through the etching mask HBM 2 may, like the etching of the first lithography, be reactive ion etching (RIE), with a fluorocarbon plasma, for example based on a gas such as carbon tetrafluoride (CF4) and/or sulphur hexafluoride (SF6) and/or nitrogen trifluoride (NF3).

In step 9, the material of the photolithography mask HBM 2 is removed. As with the removal of the residues of resin from the etching mask HBM 1 in step 6, this removal may be achieved by chemical etching with a solution of sulphuric acid (H2SO4) and hydrogen peroxide (H2O2). Following this removal, which is represented by block 46 of the block diagram of FIG. 4, the microstructure shown in FIG. 3H is obtained.

Next comes conformal deposition of a copper layer in order to fill the wells 17c so as to form the functional pads 17c, and the wells 17b so as to form the non-functional pads 17b. Advantageously, a single deposition step serves to simultaneously form all the bonding pads, namely the non-functional bonding pads 17b and the functional bonding pads 17c. Deposition may be obtained, for example by electrochemical deposition (ECD). This is the subject of steps 10, 11, 12 and 13 which will now be described. These steps form part of the group of steps represented by block 47 in the diagram of FIG. 4.

In this example, the filling of the wells 17c and 17b with copper, to create the functional bonding pads 17c and the non-functional bonding pads 17b respectively, is carried out in two steps. Such a two-step implementation makes it possible to overcome the problems of uniformity of the deposition of the copper, which result notably from the differences in the respective resistivities of the materials present on the surface to be covered: the resistivity of the layer 17 of silicon dioxide (SiO2) is generally between 10¹² and 10¹⁶ ohms centimetre (Ωcm) and the resistivity of the layer 16 of silicon nitride (SiN) which is exposed at the bottom of the wells 17b is of the order of 10¹⁶ Ωcm, whereas the resistivity of the horizontal metallizations in the metallization level MX which are exposed at the bottom of the wells 17c is 17×10⁻⁷ Ωcm, that is 1.7 μΩcm. In a first step, a copper film is deposited, in other words a thin layer of copper adapted to fully line the entire interior of the wells 17c and 17b to be filled, and to serve as copper sub-layer. This thin layer then plays the role of seed layer, for growth of a thicker bulk copper layer, for example by ECD.

To perform the electrochemical deposition, the wafer is immersed in an electrolyte solution comprising copper seed ions, the wafer 1 (and therefore in particular the copper seed layer) being configured as a cathode, in other words a negative terminal. As a variant or in addition, the copper is deposited on the seed layer from a copper source configured as an anode, in other words a positive terminal, when an electric current is passed between said positive and negative terminals. In all cases, since the electrochemical deposition reaction is a reaction controlled by an electric current, it is therefore highly sensitive to the ohmic drop on the surface to be covered. To prevent any risk of formation of voids in the patterns formed of the wells 17b and 17c when they are filled by electrochemical deposition, it is therefore ideal to have previously formed a perfectly conformal seed layer, in other words with the most constant thickness possible while following all of the hollows and/or protrusions on the surface of the microstructure. This promotes filling of the bottom of the wells 17b and 17c and prevents said wells from closing up prematurely and creating a cavity inside them. An explanation of the technological steps for attaining this result does not fall within the scope of the present description. Those skilled in the art, based on their general knowledge, will be able to refer to the corresponding technical literature where necessary, as regards notably but not exclusively deposition techniques referred to as super-fill, for example.

In practice and with reference to the block diagram of FIG. 4, step 10 comprises first of all deposition on the microstructure of a very thin sub-layer of copper by physical vapour deposition (PVD) at low and medium temperature, or by chemical vapour deposition (CVD) at medium and high temperature, so as to form the copper seed layer.

This chemical deposition is obtained in the presence of a solution containing a seed of the metal to be deposited. The seed of a metal mainly comprises ions of this metal. Rather than a monolithic covering, it may be advantageous to produce the seed layer as a film made of an alloy combining various materials each contributing their respective advantages (adhesion, melting point, density, thermal expansion coefficient, electrical resistivity, etc.). The behaviour of the seeds during deposition (volatility, vapour pressure, stability, etc.) is also a criterion for selection of the seed ion(s). To sum up, the ion compositions of the group of materials considered for forming the seed film will be selected taking into account thermodynamic, mechanical and physical criteria. In the application concerned by the invention, namely filling with copper of bonding patterns in the metallization level HBM of the wafers to be assembled by hybrid bonding, a Ti—TiN—Cu system has been found to be very suitable for vapour deposition of copper, whether physical or chemical. The corresponding solution mainly comprises copper ions, along with titanium ions and titanium nitride ions.

As a variant of a PVD or CVD method, the seed layer may be formed by reduction of a solution of ion seeds of copper and, where applicable, of the other metals selected to make up a copper alloy. To promote conformal deposition, it may be decided to go with the formation of an oxide and notably a copper oxide alone, thermodynamically more favourable than the formation of copper metal, followed by reduction of this oxide for example during annealing under reductive atmosphere.

In all of the embodiments, the thickness of the copper seed layer which is deposited is a few dozen nanometres. As stated above, this seed layer has the function of initiating electrolytic growth of the copper upon implementation of a method of electrochemical deposition (ECD) of copper. In examples of implementation, the thickness of the seed layer may be around 90 nm.

Step 11 involves deposition of the bulk copper layer per se, for example by an ECD method. This is performed, for example, by immersing the wafer in the electrolyte and applying a voltage between the wafer configured as a cathode and an anode, for example a source of copper configured as an anode. The patterns corresponding to the wells 17b and 17c already covered with the seed layer are then filled with copper by electrochemical deposition.

To ensure that the filling of the patterns is conformal, several additives may be added to the electrolyte: a suppressor, an accelerator and a leveler. The effects of these additives, described in detail below, combine to slow down deposition at the top of the trench and accelerate deposition at the bottom of the trench:
suppressors are macromolecules, such as polyethylene glycol (PEG), which have a tendency to remain at the surface of the microstructure without diffusing into the trenches, and which react with chlorides added in solution, to form a film protecting the surface and limiting the reduction of the metal at that location;
accelerators inhibit the effect of suppressors, while having a tendency to be located in the trenches. They thus allow growth of the copper in the trenches. Accelerators are often sulphide molecules, such as SPS (HSO3(CH2)3S) to cite one non-limiting example; and
levelers, such as the molecule JGB (Janus Green B), have the same type of action as suppressors, but have a tendency to be located in zones where the current is most dense (peaks, protrusions, etc.). They therefore make it possible to limit deposition at the higher points of the microstructure.

To complete the deposition of copper by ECD, a stabilizing annealing operation at high temperature may be carried out in step 12 to cause fusion at the deposition interface. Interfaces which are less sharp and therefore less fragile are thus obtained. This annealing also makes it possible to stabilize the copper layer. For example, annealing at 400° C. allows the microstructure to reach thermodynamic equilibrium.

As those skilled in the art will appreciate, instead of electrochemical deposition (ECD), use may also be made of another metal deposition method, in other words a different method for bulk copper deposition. As an alternative to the ECD method described above, a technique such as autocatalytic conversion, precipitation, crystallization, cross-linking, aggregation, or the like may be chosen for example.

In the text above, embodiments have been proposed in which the metal for filling the wells 17b and 17c in order to simultaneously form the bonding pads 17b and 17c respectively, is copper. is the embodiments are not however limited to this example. Another metal may be deposited in the wells to form the bonding pads, for example gold (Au), which may also be deposited by electrochemical deposition (ECD) using a chemical seed comprising corresponding metal ions, or titanium (Ti), aluminium (Al), niobium (Nb), or platinum (Pt), which may then be deposited preferably by a PVD method. This list of examples of metals is not limiting. Where applicable, a seed layer adapted to the growth of this metal is thus formed in step 10.

In step 13, the excess copper is removed at the top surface of the metallization level HBM, for example by chemical mechanical polishing (CMP). CMP results in a very fine nanotopographic level (less than 5 nm, for example) and guarantees a very low degree of roughness (less than 0.5 nm, for example) for hybrid bonding without defects. In other words, the implementation of step 13 produces a wafer 1 with an ultra-polished top surface. Step 13 rounds off the group of steps represented by block 47 in the block diagram of FIG. 4. The microstructure 1 shown in FIG. 3I is thus obtained.

Step 14 consists of hybrid bonding of the wafer 1 on the wafer 2, after vertically turning over the wafer 1. Naturally, the bottom wafer 2 has undergone the same treatments as the top wafer 1, in parallel. It therefore has an interconnect structure having the same characteristics as the top wafer 1. Its top surface is also ultra-polished. The bonding is direct—without adhesive—and is carried out at ambient temperature. This avoids the risk of damage and undesired interaction of an adhesive during a subsequent heat treatment, where applicable.

Step 15 may comprise bonding annealing of the 3D microstructure obtained in order to reinforce the bonding interface 60 between the wafers 1 and 2, and ensure the electrical connection between the functional bonding pads 17c and 27c of the wafers 1 and 2, respectively. For example, bonding annealing at 400° C. may be carried out for two hours. To evaluate the quality of bonding, scanning acoustic microscopy (SAM) may be used in order to detect any voids.

In a manner known per se, the back substrate 11 of the top wafer 1 is ultimately thinned, for example by a process carried out from the front of the 3D microstructure shown in FIG. 2, for example first mechanically and then chemically in order to reduce the risk of damage to the bonding interface 60.

In the block diagram of FIG. 4, steps 14 and 15 are grouped together in block 48. The result obtained following this group of steps 48 is the 3D microstructure of FIG. 2.

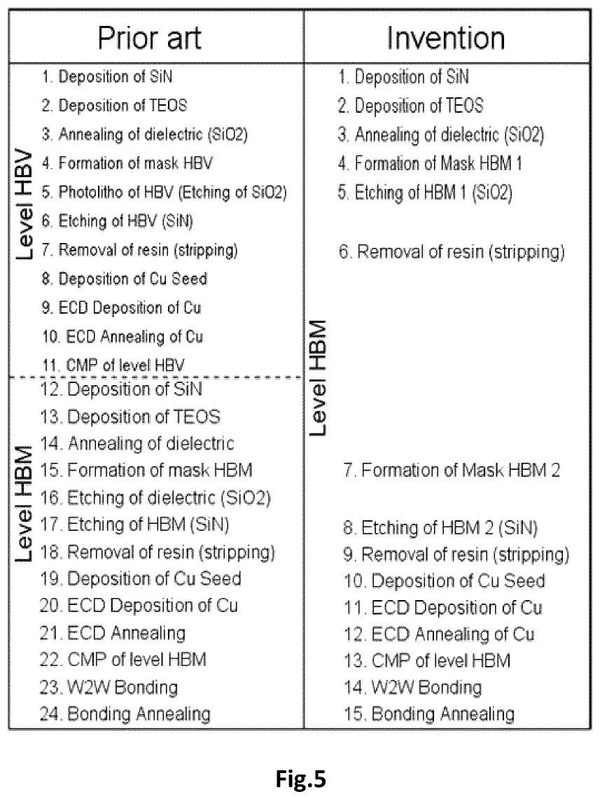

The table in FIG. 5 lists the steps in the production of the 3D microstructure according to the embodiments for implementation of the method according to the invention (right-hand column) for producing the 3D microstructure of FIG. 2 in which the upper interconnect level HBM of the interconnect structure of the wafer is directly above the horizontal interconnect level MX, in comparison to the steps of a method according to the prior art (left-hand column) for producing the conventional 3D microstructure shown in FIG. 1C, in other words having a vertical interconnect level HBV with vertical metallizations (vias) between the upper interconnect level HBM and the horizontal interconnect level MX.

As will be discerned by those skilled in the art, nine technological production steps are eliminated, which represents a significant saving notably in terms of energy balance, as well as in terms of treatment time in the clean room.

Furthermore, doing away with the metallization level HBV of the 3D microstructures of the prior art eliminates two layers of dielectric material (one in each of the top and bottom wafers stacked by hybrid bonding), in this case two layers of silicon dioxide (SiO2), which represents an improvement in terms of mechanical stress. Two insulating layers are also eliminated, namely the silicon nitride (SiN) insulating layer covering the layer of dielectric material of the metallization level HBV of the top and bottom wafers of the 3D microstructures according to the prior art.

Particular embodiments have been described above. Various variants and modifications will be clear to those skilled in the art. Notably, it goes without saying that the invention is not limited by the number of metallization levels provided for in the interconnect structure, which may include several levels such as the metallization level MX under consideration herein. Furthermore, the method according to the invention can produce a 3D microstructure by vertical integration of more than two wafers. To be specific, it is possible to repeat the operations so as to continue the vertical integration with bonding, each time, of a new wafer on top of the microstructure obtained in the previous iteration, by implementing the method according to the invention. The only constraints in this regard are those which, conventionally, relate to the capacity for going back over the surfaces in order to planarize them to allow fresh bonding, and of course the limit on the mechanical stress on the wafers which is caused by the stack.

1. A three-dimensional, or 3D, microelectronic structure for an integrated semiconductor product, said 3D microelectronic structure comprising a first microelectronic device produced on a top wafer, and a second microelectronic device produced on a bottom wafer on which the top wafer is bonded by hybrid bonding after being turned over vertically, wherein the bottom wafer and the top wafer each comprise a substantially flat substrate and an interconnect structure formed on top of said substrate, wherein:
the respective interconnect structure of each of the top and bottom wafers is a vertical stack of at least two interconnect levels directly superimposed and each comprising a hybrid layer essentially composed of a dielectric material, namely, respectively:
an upper interconnect level (HBM), with metal bonding pads formed in the dielectric material and adapted to interact with corresponding metal bonding pads in the other wafer for hybrid bonding of the top wafer to the bottom wafer; and,
a horizontal interconnect level (MX) which is directly below the upper interconnect level (HBM), with horizontal metallization elements,
the respective metal bonding pads of each of the top and bottom wafers are distributed substantially homogeneously on the top surface of the upper interconnect level (HBM) of the interconnect structure of said wafer, with a bonding pitch, defined as the maximum spacing between adjacent bonding pads horizontally in the plane of said top surface, which is below a predetermined associated threshold;
the respective metal bonding pads of each of the top and bottom wafers comprise bonding pads of a first type, which are electrically insulated from any horizontal metallization element in the horizontal interconnect level (MX) of the interconnect structure of said wafer; and,
the respective metal bonding pads of each of the top and bottom wafers further comprise bonding pads of a second type, which are each electrically coupled to at least one underlying horizontal metallization element formed in the horizontal interconnect level (MX) of the interconnect structure of said wafer.

2. The 3D microelectronic structure according to claim 1, wherein the horizontal interconnect level (MX) of the interconnect structure of each of the top and bottom wafers comprise a passivation film made of electrically insulating material that covers the layer of dielectric material of said horizontal metallization level (MX), and wherein the bonding pads of the first type of each of the top and bottom wafers are electrically insulated from any horizontal metallization element in the horizontal interconnect level (MX) of the interconnect structure of said wafer, at least by the insulating material of the passivation film covering the layer of dielectric material of said horizontal metallization level (MX).

3. The 3D microelectronic structure according to claim 1, wherein the layer of dielectric material of the upper interconnect level (HBM) of the interconnect structure of each of the top and bottom wafers is a hybrid layer of dielectric material with patterns, said patterns defining:
solid zones of said dielectric material;
first vertical through zones filled with metal and at which the insulating material of the passivation layer of the horizontal interconnect level (MX) is present, said first through zones forming the bonding pads of the first type of the upper interconnect level (HBM); and,
second vertical through zones, filled with metal, and at which the passivation layer of the horizontal interconnect level (MX) has an opening, said second through zones forming the bonding pads of the second type of the upper interconnect level (HBM), each in electrical continuity with one of the horizontal metallization elements of the horizontal interconnect level (MX) through said opening in the passivation layer.

4. The 3D microelectronic structure according to claim 1, wherein the associated threshold of the bonding pitch is lower than or equal to 10 μm.

5. The 3D microelectronic structure according to claim 1, wherein the dielectric material of the hybrid interconnect layers of the interconnect structure of each of the top and bottom wafers is silicon dioxide (SiO2).

6. The 3D microelectronic structure according to claim 1, wherein the material constituting the metal bonding pads of the upper interconnect level (HBM) and/or the material constituting the horizontal metallizations of the horizontal interconnect level (MX) of the interconnect structure of each of the top and bottom wafers is a metal selected from the group comprising copper (Cu), gold (Au), titanium (Ti), aluminium (Al), niobium (Nb), and platinum (Pt), or an alloy based on at least one of said metals.

7. The 3D microelectronic structure according to claim 1, wherein the electrically insulating material of the passivation film of the horizontal interconnect level (MX) of the interconnect structure of each of the top and bottom wafers is a silicon nitride (SiN) or a silicon carbonitride (SiCN).

8. The 3D microelectronic structure according to claim 1, wherein the substrate of the top wafer and/or the substrate of the bottom wafer each comprise an active zone with active elements in the upper part of said substrate, and wherein:
the bonding pads of the first type of the interconnect structure of each of the top and bottom wafers are electrically insulated from the active elements of the active zone of the substrate of said wafer, whereas,
at least some of the bonding pads of the second type of the interconnect structure of the top wafer and/or of the bottom wafer are electrically coupled to at least one of the active elements of the active zone of the substrate of said wafer.

9. A method for producing a three-dimensional, or 3D, microelectronic structure, according to claim 1, comprising the hybrid bonding of a top wafer on a bottom wafer after turning said top wafer over vertically,
wherein the prior production of the interconnect structure of each of the top and bottom wafers comprises the formation of a vertical stack of at least two interconnect levels directly superimposed on top of the substrate of said wafer, namely, respectively:
a horizontal interconnect level (MX), with horizontal metallization elements formed in the dielectric material of a corresponding hybrid layer; and, directly on top of said horizontal interconnect level (MX),
an upper interconnect level (HBM) with metal bonding pads formed in the dielectric material of a corresponding hybrid layer, and adapted to interact with corresponding metal bonding pads in the other wafer, for the hybrid bonding of the top wafer on the bottom wafer,
wherein said method further comprising:
the respective metal bonding pads of the upper metallization level (HBM) of the interconnect structure of each of the top and bottom wafers are produced with a substantially homogeneous distribution on the top surface of said upper metallization level (HBM), and with a bonding pitch, defined as the maximum spacing between adjacent bonding pads horizontally in the plane of said top surface, which is below a predetermined associated threshold;
among the respective metal bonding pads of each of the top and bottom wafers, bonding pads of a first type are produced each with electrical insulation from any horizontal metallization element in the horizontal interconnect level (MX) of the interconnect structure of said wafer;
among the respective bonding pads of each of the top and bottom wafers, furthermore, bonding pads of a second type are produced each in electrical continuity with at least one underlying horizontal metallization element formed in the horizontal interconnect level (MX) of the interconnect structure of said wafer.

10. The method according to claim 9, wherein the formation of the upper interconnect level (HBM) of the interconnect structure of each of the top and bottom wafers comprises:
depositing a passivation film made of electrically insulating material that covers a hybrid layer of dielectric material comprising horizontal metallization elements in the horizontal metallization level (MX) of the wafer;
formation of a layer of dielectric material and first etching by photolithography, in order to etch said layer of dielectric material with an etch stop on the passivation film of the horizontal metallization level (MX) in order to form patterns in said layer of dielectric material corresponding to the metal bonding pads in the upper metallization level (HBM) of the wafer; then,
second etching by photolithography, in order to etch the passivation film of the horizontal metallization level (MX) so as to open up said film in only some of the patterns previously formed in the layer of dielectric material which correspond to the metal bonding pads of the second type in the upper metallization level (HBM) of the wafer; then,
simultaneously filling, with metal, all of the patterns previously formed in the layer of dielectric material, namely both the patterns corresponding to the metal bonding pads of the first type and the patterns corresponding to the metal bonding pads of the second type in the upper metallization level (HBM) of the wafer.

11. The method according to claim 10, wherein the patterns in the layer of dielectric material corresponding to the metal bonding pads in the upper metallization level (HBM) of the wafer are filled with metal by electrochemical deposition.
